(19) United States
(12) Patent Application Publication
(10) Pub. No.: US 2025/0067664 A1
(43) Pub. Date: Feb. 27, 2025

(54) DETERMINATION METHOD AND SUBSTRATE PROCESSING APPARATUS

(71) Applicant: TOKYO ELECTRON LIMITED, Tokyo (JP)

(72) Inventors: Hirokazu UEDA, Osaka (JP); Masafumi ASANO, Tokyo (JP); Takanobu KAITSUKA, Yamanashi (JP); Yuji OTSUKI, New York, NY (US); Yasutoshi UMEHARA, Tokyo (JP)

(21) Appl. No.: 18/726,285

(22) PCT Filed: Dec. 23, 2022
(86) PCT No.: PCT/JP2022/047531

§ 371 Date: Jul. 2, 2024

(30) Foreign Application Priority Data
Jan. 6, 2022 (JP) 2022-000835
Aug. 18, 2022 (JP) 2022-130653

(51) Int. Cl. G01N 21/3563; B23K 26/364; C23C 16/02; C23C 16/04; C23C 16/52; G01N 21/95

(52) U.S. Cl. CPC G01N 21/3563; B23K 26/364; C23C 16/0263; C23C 16/045; C23C 16/52; G01N 21/9501

(57) ABSTRACT

There is provided a determination method comprising: a post-embedding measurement step for performing spectroscopic measurement on a substrate in which a pattern including a recess is formed, the recess having an embedding material embedded therein, and measuring an absorbance spectrum of the substrate having the embedding material embedded therein; and a determination step for determining an embedded state of the recess based on an integrated value of an intensity of the measured absorbance spectrum of the substrate at a plurality of wavenumbers.

### TECHNICAL FIELD

The present disclosure relates to a determination method and a substrate processing apparatus.

### BACKGROUND

Patent Document 1 discloses a technique for filling a recess without a gap in the case of forming a SiN film to fill a recess formed in an SiO₂ film on a surface of a wafer.

### PRIOR ART DOCUMENTS

### Patent Documents

Patent Document 1: Japanese Patent Application Publication No. 2017-174902

### SUMMARY

### Problems to Be Resolved by the Invention

The present disclosure provides a technique for detecting occurrence of embedding defects.

### Means for Solving the Problems

The determination method according to one aspect of the present disclosure includes a step for performing spectroscopic measurement on a substrate in which a pattern including a recess is formed, the recess having an embedding material embedded therein, and measuring the absorbance spectrum of the substrate having the embedding material embedded therein; and a step for determining the embedded state of the recess based on an integrated value of the intensity of the measured absorbance spectrum of the substrate at a plurality of wavenumbers.

Specifically, “absorbance spectrum” may be considered to be equivalent to an area integrated value (difference) of a wavelength range of “reflectance spectrum” obtained from reflected light. In other words, “absorbance spectrum” can be used as the amount of change in “reflectance spectrum.”

### Effect of the Invention

In accordance with the present disclosure, the occurrence of embedding defects can be detected.

### BRIEF DESCRIPTION OF THE DRAWINGS

FIG. 1 is a schematic cross-sectional view showing an example of a schematic configuration of a film forming apparatus according to a first embodiment.

FIG. 2 shows a state in which a substrate is lifted from a placing table in the film forming apparatus according to the first embodiment.

FIG. 3 is a schematic configuration diagram showing another example of the film forming apparatus according to the first embodiment.

FIG. 4 shows an example of a substrate before film formation according to the first embodiment.

FIG. 5 shows an example of a substrate after film formation according to the first embodiment.

FIG. 6 shows an example of a spot size of measurement light in spectroscopic measurement according to the first embodiment.

FIG. 7 shows an absorbance spectrum of a substrate according to the first embodiment.

FIG. 8A shows an example of a substrate according to the first embodiment.

FIG. 8B shows an example of a substrate according to the first embodiment.

FIG. 9 shows an example of relationship between an integrated value of an absorbance spectrum and a film thickness of a formed film according to the first embodiment.

FIG. 10 shows an example of a substrate according to the first embodiment.

FIG. 11 shows an example of relationship between an integrated value of an absorbance spectrum and a film thickness of a formed film according to the first embodiment.

FIG. 12 shows an example of a substrate W according to the first embodiment.

FIG. 13 shows an example of relationship between an integrated value of an absorbance spectrum and a film thickness of a formed film according to the first embodiment.

FIG. 14 is a flowchart showing an example of flow of substrate processing according to the first embodiment.

FIG. 15 shows an example of a substrate as a sample.

FIG. 16 shows examples of integrated values of intensities of absorbance spectra of samples.

FIG. 17 shows an example of a substrate according to a second embodiment.

FIG. 18 shows an example of relationship between an integrated value of an absorbance spectrum and a film thickness of a formed film according to the second embodiment.

FIG. 19 shows an example of relationship between an integrated value of an absorbance spectrum and a film thickness of a formed film according to the second embodiment.

FIG. 20 shows an example of relationship between a difference and a film thickness of a formed film according to the second embodiment.

FIG. 21 shows an example of a substrate according to the second embodiment.

FIG. 22 shows an example of relationship between an integrated value of an absorbance spectrum and a film thickness of a formed film according to the second embodiment.

FIG. 23 shows an example of relationship between a difference and a film thickness of a formed film according to the second embodiment.

FIG. 24 shows an example of a substrate according to the second embodiment.

FIG. 25 shows an example of relationship between an integrated value of an absorbance spectrum and a film thickness of a formed film according to the second embodiment.

FIG. 26 is a flowchart showing an example of flow of substrate processing according to the second embodiment.

FIG. 27 is a schematic configuration diagram showing another example of a film forming apparatus according to an embodiment.

FIG. 28 shows an example of a schematic configuration of a measuring part according to an embodiment.

FIG. 29 shows another example of a schematic configuration of a measuring part according to the embodiment.

FIG. 30 shows an example of a reflectance spectrum.

FIG. 31 shows an example of void detection using a reflectance spectrum according to an embodiment.

### DETAILED DESCRIPTION

Hereinafter, embodiments of a determination method and a substrate processing apparatus of the present disclosure will be described in detail with reference to the accompanying drawings. Further, the following embodiments are not intended to limit the determination method and the substrate processing apparatus of the present disclosure.

In manufacturing semiconductor devices, a film forming apparatus forms a conductive film or an insulating film on a substrate such as a semiconductor wafer on which a pattern including a recess is formed. The film forming apparatus places a substrate in a chamber having a predetermined vacuum level, supplies a film forming source gas into the chamber, and forms a film on a substrate using reaction support energy such as heat or plasma. Thermal chemical vapor deposition (CVD), thermal atomic layer deposition (ALD), plasma enhancement CVD (PE-CVD), plasma enhancement ALD (PE-ALD), and the like are known as film forming techniques.

The miniaturization and three-dimensionalization of a pattern formed on a substrate are progressing. However, when performing film formation such as a process of filling a recess of a miniaturized aspect pattern in a substrate, embedding defects in which the recess is embedded in a state where a gap is formed may occur since a conductive film or an insulating film is not normally embedded therein.

Therefore, a technique for detecting occurrence of embedding defects is expected.

### Embodiments

### Device Configuration

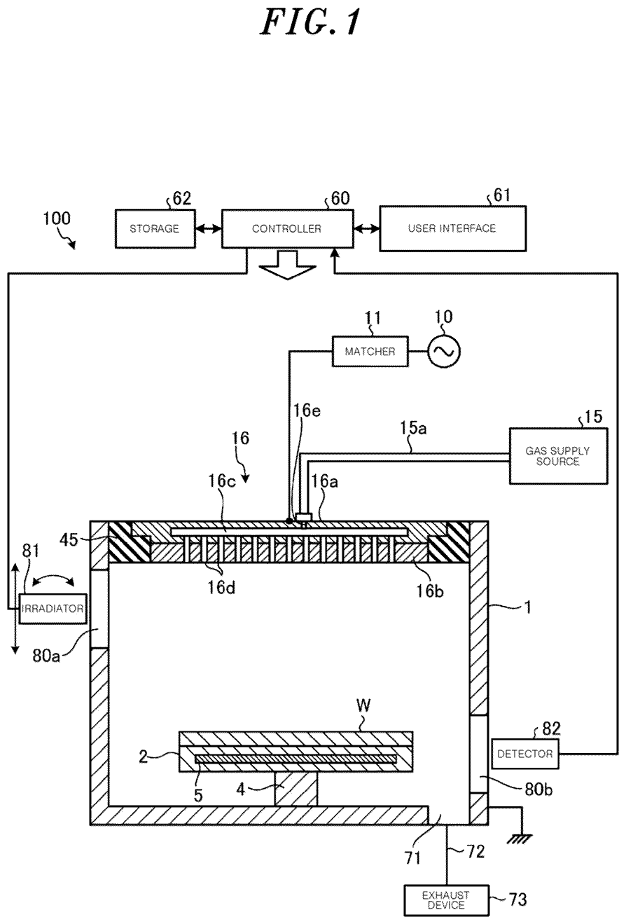

Next, a first embodiment will be described. First, an example of a substrate processing apparatus of the present disclosure will be described. Hereinafter, a case where the substrate processing apparatus of the present disclosure is the film forming apparatus 100 and the film forming apparatus 100 performs film formation as substrate processing will be mainly described. FIG. 1 is a schematic cross-sectional view showing an example of a schematic configuration of the film forming apparatus 100 according to the first embodiment. In the present embodiment, the film forming apparatus 100 corresponds to the substrate processing apparatus of the present disclosure. The film forming apparatus 100 is an apparatus for forming a film on a substrate W in one embodiment. The film forming apparatus 100 shown in FIG. 1 includes a chamber 1 that is maintained in an airtight state and is electrically grounded. The chamber 1 is formed in a cylindrical shape, and is made of aluminum, aluminum oxide, or the like, having an anodically oxidized surface, for example. A placing table 2 is disposed in the chamber 1.

The placing table 2 is made of ceramic or a metal such as aluminum, nickel, aluminum oxide, aluminum nitride, or the like. The substrate W such as a semiconductor wafer is placed on the upper surface of the placing table 2. A pattern including a recess is formed on the substrate W. The placing table 2 horizontally supports the substrate W placed thereon. The bottom surface of the placing table 2 is electrically connected to a support member 4 made of a conductive material. The placing table 2 is supported by the support member 4. The support member 4 is supported on the bottom surface of the chamber 1. The lower end of the support member 4 is electrically connected to the bottom surface of the chamber 1 and grounded via the chamber 1. The lower end of the support member 4 may be electrically connected to the bottom surface of the chamber 1 via a circuit that is adjusted to lower an impedance between the placing table 2 and the ground potential.

A heater 5 is embedded in the placing table 2, and the substrate W placed on the placing table 2 can be heated to a predetermined temperature by the heater 5. A channel (not shown) for circulating a coolant is formed in the placing table 2, and a coolant whose temperature is controlled by a chiller unit disposed outside the chamber 1 may be supplied and circulated in the channel. The placing table 2 may control the substrate W to a predetermined temperature by heating using the heater 5 and cooling using the coolant supplied from the chiller unit. Further, the placing table 2 may not be provided with the heater 5, and the temperature of the substrate W may be controlled only by the coolant supplied from the chiller unit.

Further, an electrode may be embedded in the placing table 2. Due to the electrostatic force generated by a DC voltage supplied to the electrode, the placing table 2 can attract the substrate W placed on the upper surface thereof.

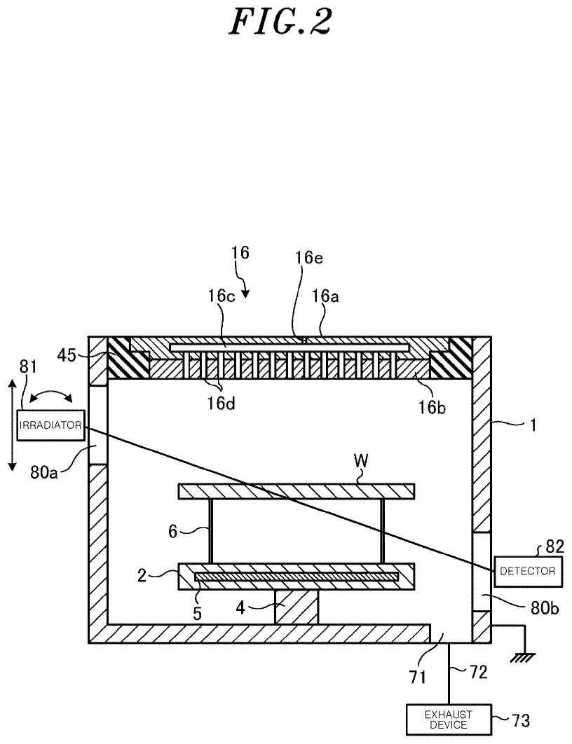

The placing table 2 is provided with lifter pins 6 for raising and lowering the substrate W. In the film forming apparatus 100, in the case of transferring the substrate W or performing spectroscopic measurement on the substrate W, the lifter pins 6 protrude from the placing table 2 to lift the substrate W from the placing table 2 while supporting the substrate W from the backside thereof. FIG. 2 shows a state in which the substrate W is lifted from the placing table 2 in the film forming apparatus 100 according to the first embodiment. The substrate W is transferred to the film forming apparatus 100. A loading/unloading port (not shown) for loading/unloading the substrate W is formed on a sidewall of the chamber 1, for example. A gate valve for opening and closing the loading/unloading port is disposed at the loading/unloading port. In the case of loading and unloading the substrate W, the gate valve is opened. The substrate W is loaded into the chamber 1 from the loading/unloading port by a transfer mechanism (not shown) in a transfer chamber. The film forming apparatus 100 controls a lifting mechanism (not shown) disposed outside the chamber 1 to raise the lifter pins 6 and receive the substrate W from the transfer mechanism. After the transfer mechanism retreats, the film forming apparatus 100 controls the lifting mechanism to lower the lifter pins 6 and place the substrate W on the placing table 2.

A shower head 16 formed in a substantially disc shape is disposed on an inner surface of the chamber 1 to be located above the placing table 2. The shower head 16 is supported at an upper portion of the placing table 2 via an insulating member 45 made of ceramic or the like. Accordingly, the chamber 1 and the shower head 16 are electrically insulated. The shower head 16 is made of a conductive metal such as nickel or the like.

The shower head 16 includes a ceiling plate member 16a and a shower plate 16b. The ceiling plate member 16a is disposed to close the chamber 1 from above. The shower plate 16b is disposed below the ceiling plate member 16a to face the placing table 2. A gas diffusion space 16c is formed in the ceiling plate member 16a. A plurality of gas injection holes 16d that are opened toward the gas diffusion space 16c are distributed and formed in the ceiling plate member 16a and the shower plate 16b.

A gas inlet port 16e for introducing various gases into the gas diffusion space 16c is formed in the ceiling plate member 16a. A gas supply line 15a is connected to the gas inlet port 16e. A gas supply source 15 is connected to the gas supply line 15a.

The gas supply source 15 has gas supply lines connected to gas supply sources of various gases used for film formation. The gas supply lines are branched appropriately to correspond to processes of film formation, and are provided with control devices for controlling flow rates of gases, e.g., valves such as on-off valves and flow rate controllers such as mass flow controllers. The gas supply source 15 can control the flow rates of various gases by controlling the control devices such as on-off valves or flow rate controllers disposed in the gas supply lines.

The gas supply source 15 supplies various gases used for film formation to the gas supply line 15a. For example, the gas supply source 15 supplies a film forming source gas to the gas supply line 15a. Further, the gas supply source 15 supplies a reaction gas that reacts with a purge gas and a source gas to the gas supply line 15a. The gas supplied to the gas supply line 15a is diffused in the gas diffusion space 16c and injected from the gas injection holes 16d.

The space surrounded by the bottom surface of the shower plate 16b and the upper surface of the placing table 2 forms a processing space in which film formation is performed. Further, the shower plate 16b and the placing table 2 are configured as a pair of electrode plates for producing capacitively coupled plasma (CCP) in the processing space. A radio frequency (RF) power supply 10 is connected to the shower head 16 via a matcher 11. By applying an RF power to a gas supplied from the RF power supply 10 to the processing space 40 via the shower head 16 and supplying a gas from the shower head 16, plasma is produced in the processing space. Further, the RF power supply 10 may be connected to the placing table 2 instead of being connected to the shower head 16, and the shower head 16 may be grounded.

An exhaust port 71 is formed at the bottom portion of the chamber 1. An exhaust device 73 is connected to the exhaust port 71 via an exhaust line 72. The exhaust device 73 has a vacuum pump and a pressure control valve. The exhaust device 73 can reduce and adjust a pressure in the chamber 1 to a predetermined vacuum level by operating the vacuum pump or the pressure control valve.

The film forming apparatus 100 can perform spectroscopic measurement on the substrate W in the chamber 1 to detect a state of a film formed on the substrate W. The spectroscopic measurement can be performed by a method for irradiating light onto the substrate W and measuring light (transmitted light) that has passed through the substrate W (transmission method), and a method for measuring light (reflected light) reflected from the substrate W (reflection method). The film forming apparatus 100 shown in FIG. 1 has a configuration in which the transmitted light that has transmitted through the substrate W is measured, for example. Windows 80a and 80b are formed on sidewalls facing each other with the placing table 2 interposed therebetween in the chamber 1. The window 80a is disposed at a high position on the sidewall. The window 80b is disposed at a low position on the sidewall. A member that can transmit light, e.g., quartz or the like, is fitted to the windows 80a and 80b, thereby sealing the windows 80a and 80b. An irradiator 81 that irradiates light is disposed outside the window 80a. A detector 82 capable of detecting light is disposed outside the window 80b.

In the case of performing spectroscopic measurement by the transmission method, in the film forming apparatus 100, the lifter pins 6 protrude from the placing table 2 to lift the substrate W from the placing table 2, as shown in FIG. 2. The positions of the window 80a and the irradiator 81 are adjusted such that the light irradiated from the irradiator 81 is irradiated onto the upper surface of the lifted substrate W through the window 80a. Further, the positions of the window 80b and the detector 82 are adjusted such that the light that has transmitted through the lifted substrate W is incident on the detector 82 through the window 80b.

In the spectroscopic measurement, it is preferable that the measurement light irradiated onto the substrate W can transmit through the substrate W. For example, when the substrate W is a silicon substrate, in the spectroscopic measurement, it is preferable to irradiate infrared light that can transmit through the silicon substrate. For example, in the case of forming a SiO film or a SiN film as an embedding material by CVD, the wavelength of the measurement light may be a short wavelength shorter than that of infrared light, e.g., light of a visible light range. In particular, when a recess formed in the substrate W has a relatively small depth, the measurement light may be light having a short wavelength of about 0.1 μm to 0.22 μm.

The film forming apparatus 100 according to the present embodiment performs, as spectroscopic measurement, analysis by an infrared spectroscopy (IR) method using infrared light, and detects a state of a film formed on the substrate W. The irradiator 81 irradiates infrared light. The detector 82 detects infrared light that has transmitted through the substrate W. The irradiator 81 is disposed such that the irradiated infrared light reaches a predetermined region near the center of the lifted substrate W through the window 80a. The detector 82 is disposed such that the transmitted light that has transmitted through a predetermined region of the substrate W is incident through the window 80b.

In the film forming apparatus 100 according to the present embodiment, in the spectroscopic measurement, a state of a film formed on the substrate W is detected by obtaining the absorbance for each wavenumber of the transmitted light that has transmitted through the substrate W. Specifically, in the film forming apparatus 100, embedding defects in the film formed on the substrate W are detected by obtaining the absorbance for each wavenumber of the transmitted light that has transmitted through the substrate W using Fourier transform infrared spectroscopy.

The irradiator 81 has therein a light source that emits infrared light, or an optical element such as a mirror or lenses, and is configured to emit interfered infrared light. For example, the irradiator 81 uses a half mirror or the like to split an optical path of infrared light generated by the light source into two optical paths at an intermediate part thereof, causes interference by changing an optical path difference by making a length of one optical path different from a length of the other optical path, and irradiates infrared light of various interference waves with different optical path differences. Further, the irradiator 81 may include a plurality of light sources, and irradiate infrared light of various interference waves with different optical path differences by controlling infrared lights of the light sources using an optical element. In the present embodiment, the irradiator 81 corresponds to the light source of the present disclosure.

The detector 82 detects the signal intensity of the transmitted light by the infrared light of various interference waves that has transmitted through the substrate W. In the present embodiment, the detector 82 corresponds to a light receiving mechanism of the present disclosure.

The overall operation of the film forming apparatus 100 configured as described above is controlled by the controller 60. A user interface 61 and a storage part 62 are connected to the controller 60.

The user interface 61 includes an operation part such as a keyboard through which a process manager inputs commands to manage the film forming apparatus 100, and a display part such as a display that visualizes and displays an operation status of the film forming apparatus 100. The user interface 61 receives various operations. For example, the user interface 61 receives a predetermined operation of instructing start of plasma processing.

The storage part 62 stores programs (software) for implementing various processes executed by the film forming apparatus 100 under the control of the controller 60, or data such as processing conditions, process parameters, or the like. The programs or the data may be stored in a computer-readable computer recording medium (e.g., a hard disk, a CD, a flexible disk, a semiconductor memory, or the like). Alternatively, the programs or the data may be transmitted in real time from another device through a dedicated line, for example, and used online.

The controller 60 is, e.g., a computer including a processor, a memory, and the like. The controller 60 reads out the programs or the data from the storage part 62 based on instructions from the user interface 61, and controls individual components of the film forming apparatus 100, thereby performing substrate processing to be described later.

The controller 60 is connected to the irradiator 81 and the detector 82 via an interface (not shown) that inputs and outputs data, and inputs and outputs various information. The controller 60 controls the irradiator 81 and the detector 82. For example, the irradiator 81 irradiates various interference waves with different optical path differences based on the control information from the controller 60. Further, the controller 60 inputs data on a signal intensity of the infrared light detected by the detector 82.

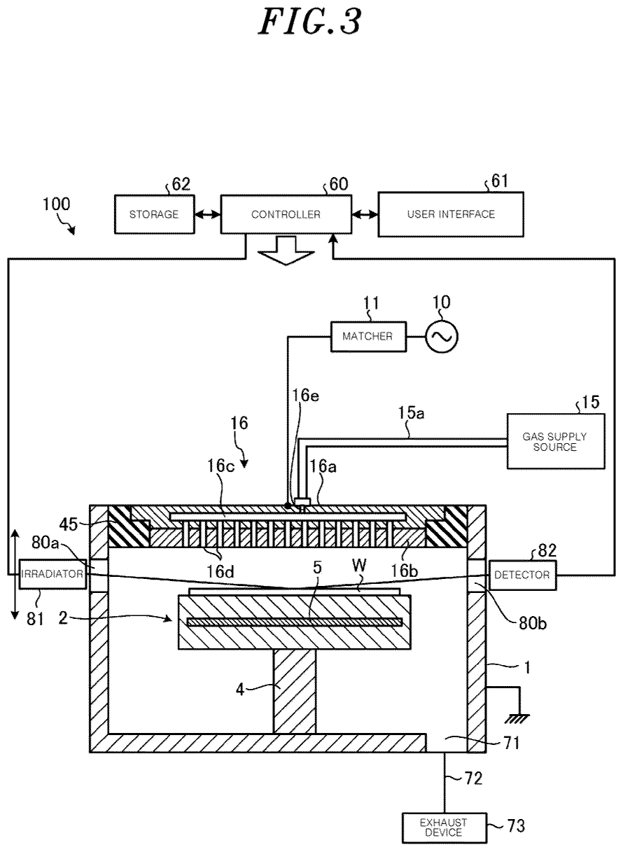

Here, in FIGS. 1 and 2, an example in which the film forming apparatus 100 is configured to measure transmitted light that has transmitted through the substrate W so that spectroscopic measurement using a transmission method can be performed has been described. However, the film forming apparatus 100 may be configured to perform spectroscopic measurement using a reflection method. FIG. 3 is a schematic configuration diagram showing another example of the film forming apparatus 100 according to the first embodiment. The film forming apparatus 100 shown in FIG. 3 shows an example of a configuration in which reflected light reflected from the substrate W is measured.

In the film forming apparatus 100 shown in FIG. 3, the windows 80a and 80b are provided on the sidewalls of the chamber 1 facing each other with the placing table 2 interposed therebetween. The irradiator 81 for irradiating light is provided outside the window 80a. The detector 82 capable of detecting light is provided outside the window 80b. The positions of the window 80a and the irradiator 81 are adjusted such that the light irradiated from the irradiator 81 is irradiated onto the substrate W through the window 80a. Further, the positions of the window 80b and the detector 82 are adjusted such that the light reflected by the substrate W is incident on the detector 82 through the window 80b. Further, a loading/unloading port (not shown) for loading/unloading the substrate W is provided on the sidewall of the chamber 1 different from the sidewalls where the windows 80a and 80b are disposed. A gate valve for opening and closing the loading/unloading port is provided at the loading/unloading port.

The film forming apparatus 100 according to the present embodiment performs, as spectroscopic measurement, analysis using infrared spectroscopy using infrared light, and detects the state of the film formed on the substrate W. The irradiator 81 irradiates infrared light. The detector 82 detects infrared light reflected from the substrate W. The irradiator 81 is disposed such that the irradiated infrared light reaches a predetermined region near the center of the substrate W through the window 80a. The detector 82 is disposed such that infrared light reflected from the predetermined region of the substrate W is incident through the window 80b. In this manner, the film forming apparatus 100 shown in FIG. 3 can perform analysis of infrared spectroscopy using a reflection method.

The film forming apparatus 100 according to the first embodiment may be configured to be able to change the incident angle and the irradiation position of light incident on the substrate W from the irradiator 81. For example, in FIGS. 1 and 3, the irradiator 81 is configured to be vertically movable and rotatable by a driving mechanism (not shown), and the incident angle and the irradiation position of the light incident on the substrate W from the irradiator 81 can be controlled.

Next, a flow of performing film formation as substrate processing on the substrate W using the film forming apparatus 100 according to the first embodiment will be briefly described. The substrate W is placed on the placing table 2 by a transfer mechanism such as a transfer arm (not shown) or the like. The substrate W has a pattern including a recess formed thereon. When the film forming apparatus 100 performs film formation on the substrate W, the pressure in the chamber 1 is reduced by the exhaust device 73. In the film forming apparatus 100, various gases used for film formation are supplied from the gas supply source 15, and a processing gas is introduced into the chamber 1 from the shower head 16. Then, in the film forming apparatus 100, an RF power is supplied from the high frequency power supply 10 to generate plasma in the processing space, and film formation is performed on the substrate W.

Due to the miniaturization of the semiconductor devices, the pattern formed on the substrate W has a complicated shape in a nanoscale. For example, in the manufacturing process of very large scale integration (VLSI) semiconductors, the miniaturization has already progressed to a nanometer (nm) range, and the market demand for higher integration has led not only to miniaturization but also to three-dimensionalization. In the film formation using plasma, embedding failure in which a recess included in a fine pattern is filled in a state where a gap is formed may occur. Such a gap is referred to as a void, a seam, or the like. Hereinafter, the gap formed in the recess is referred to as a void.

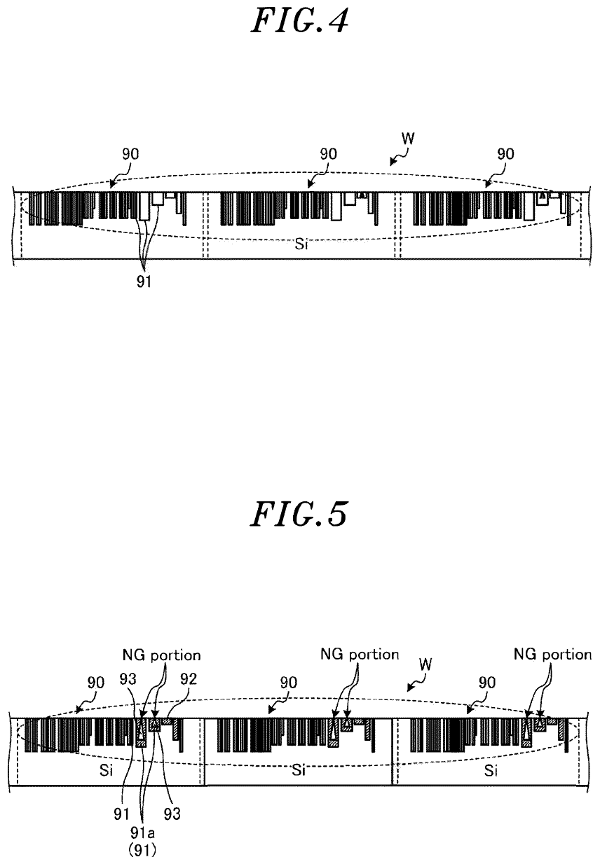

FIG. 4 shows an example of the substrate W before film formation according to the first embodiment. FIG. 4 shows a schematic cross section of the substrate W. The substrate W is made of silicon (Si), for example. A pattern 90 is formed on the substrate W to correspond to regions that will become chips of a semiconductor device. The pattern 90 includes recesses 91 of various shapes and depths. FIG. 5 shows an example of the substrate W after film formation according to the first embodiment. FIG. 5 schematically shows a state in which a film 92 is formed on the pattern 90 having the recesses 91. As a result of the film formation, some recesses 91a of the substrate W are not completely filled with the film 92, so that voids 93 that are gaps are formed in the recesses 91a. In FIG. 5, the recesses 91 in which the voids 93 have occurred are indicated as “NG potion.”

Therefore, the film forming apparatus 100 according to the first embodiment performs spectroscopic measurement on the substrate W, and detects the state of the film formed on the substrate W based on the spectroscopic measurement result. For example, in the film forming apparatus 100, the irradiator 81 irradiates infrared light to the substrate W, and the detector 82 detects the infrared light that has transmitted through the substrate W or the reflected infrared light and performs spectroscopic measurement, thereby measuring the absorbance spectrum of the substrate W in which the embedding material is embedded. Then, the film forming apparatus 100 determines the embedded state of the recess 91 based on the integrated value of the intensity of the measured absorbance spectrum of the substrate W at a plurality of wavenumbers.

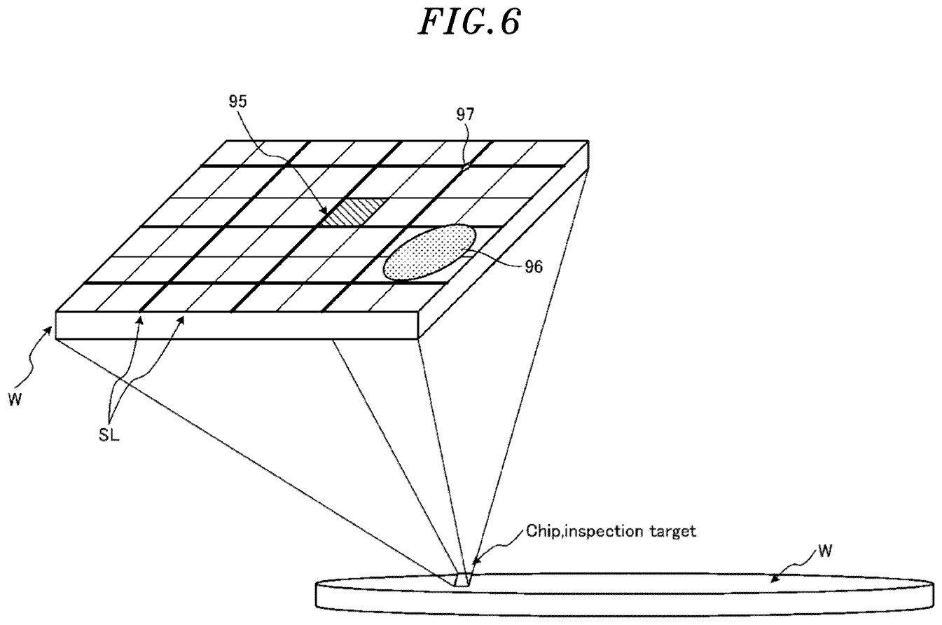

The spot size of the light (measurement light) irradiated onto the substrate W in the spectroscopic measurement will be described. FIG. 6 shows an example of the spot size of the measurement light in the spectroscopic measurement according to the first embodiment. FIG. 6 schematically shows the substrate W, and shows an enlarged part of the substrate W. FIG. 6 shows scribe lines SL for dividing the substrate W into chips. On the substrate W, the pattern 90 is formed in each region that will become a chip. For example, each region 95 surrounded by the scribe lines SL becomes a chip.

It is preferable that a spot size 96 of the measurement light is large enough to cover the pattern 90 of one region 95 that will each become a chip. For example, it is preferable that the spot size 96 of the measurement light is larger than the chip. For example, when the chip is formed with a size of 0.5 cm² to 2.0 cm², it is preferable that the spot size 96 of the measurement light is large enough to cover a region of 0.5 cm² to 2.0 cm². For example, if the spot size (area) of the measurement light irradiated from the irradiator 81 has a diameter (φ) of about 1 mm, the spot size 96 of the measurement light irradiated onto the substrate W can be increased to a diameter of about 5 mm to 2 cm by attaching and using a measurement collimator capable of changing only the spot size without changing the optical axis vector. By increasing the spot size 96 of the measurement light, the embedded state of the entire pattern 90 in the region 95 can be detected. Further, by increasing the spot size 96 of the measurement light, it is possible to obtain optical information by enlargement and averaging of the measurement size.

Further, when the spot size 96 of the measurement light cannot cover the pattern 90 of each region 95 of the substrate W, the measurement may be performed multiple times while shifting the measurement position where the measurement light is irradiated, and the averaging processing or the integration processing of adding the measured data after the measurement may be performed.

Here, as a technique for in-line inspection of a sample to be processed such as a substrate W, inspection by Raman spectroscopy using a short wavelength laser is generally known. However, in the inspection by Raman spectroscopy, only state information near the outermost surface of a sample to be measured embedded in a fine pattern is obtained. Therefore, in order to determine the quality of the film embedded in the recess 91 (whether or not a defective hole such as a void or the like exists), it is required to control the alignment for each inspection location of the substrate W, such as accurate positioning of the pattern 90 with respect to the recess 91 or adjustment of the measurement spot size. This does not cause many problems in the case where only samples having an arbitrarily determined sample pattern for development are measured at the research and development stage. However, in the case of mass production in a factory or the like, various types of LS1-Wafers are used for various purposes, and the samples to be measured are likely to be measured in multiple processes, which causes major operational challenges. For reference, FIG. 6 shows a spot size 97 of measurement light commonly used in Raman spectroscopy. In the Raman spectroscopy, the spot size 97 of the measurement light is narrowed in order to accurately obtain the state information of the inspection target location. Therefore, in order to realize in-line measurement using Raman spectroscopy, it is required to provide a positioning stage having a high-precision camera to position the measurement light at the inspection target location of the chip on the substrate W with high precision. Further, an operation of setting an algorithm for determining success or failure of the measurement result for each inspection target location becomes a heavy burden.

On the other hand, in the film forming apparatus 100 according to the first embodiment, by increasing the spot size 96 of the measurement light, the embedded state of the entire pattern 90 in the region 95 can be detected without highly accurate alignment. Accordingly, the film forming apparatus 100 can detect the occurrence of embedding defects in the substrate W in-line.

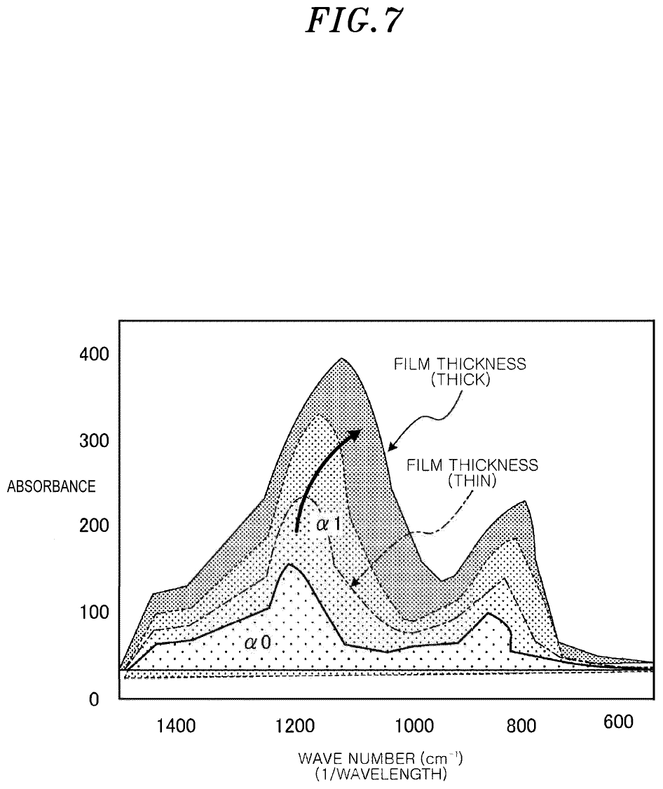

FIG. 7 shows the absorbance spectrum of the substrate W according to the first embodiment. FIG. 7 shows an example of changes in a film thickness of a film formed on the substrate W and an absorbance spectrum. The absorbance spectrum shows the absorbance of the substrate W on which a film is formed for each wavenumber. As the film thickness of the film formed on the substrate W increases, the absorbance for each wavenumber increases in the absorbance spectrum.

The controller 60 measures the absorbance spectrum indicating the absorbance of infrared light for each wavenumber of transmitted light or reflected light from the signal intensity data detected by the detector 82. The controller 60 determines the embedded state of the recess 91 based on the integrated value of the intensity of the measured absorbance spectrum of the substrate W at a plurality of wavenumbers. For example, the controller 60 calculates the integrated value of the intensity of the absorbance spectrum for a predetermined wavenumber range. The controller 60 determines the embedded state of the recess 91 based on the calculated integrated value.

The predetermined wavenumber range for integrating the intensity is set to a range including a wavenumber at which the intensity changes depending on the thickness of the film 92. The predetermined wavenumber range preferably includes a wavenumber at which a peak occurs due to the film 92 in the absorbance spectrum of the substrate W. For example, in the case of forming an SiO film or an SiN film to fill the recesses 91, the predetermined wavenumber range preferably includes a part or all of the range of 500 cm⁻¹ to 1400 cm⁻¹ or the range of 3000 cm⁻¹ to 10000 cm⁻¹. Further, the predetermined wavenumber range preferably includes the vicinity of the highest peak occurring between 800 cm⁻¹ and 1100 cm⁻¹. In the case of filling the recesses 91 by forming an SiO film, it is more preferable that the predetermined wavenumber range includes the vicinity of the peak 1080 cm⁻¹ that exhibits strong Si-O. For example, in the case of filling the recesses 91 by forming an SiO film, the controller 60 calculates the integrated value of the intensity of the absorbance spectrum for 500 cm⁻¹ to 1400 cm⁻¹.

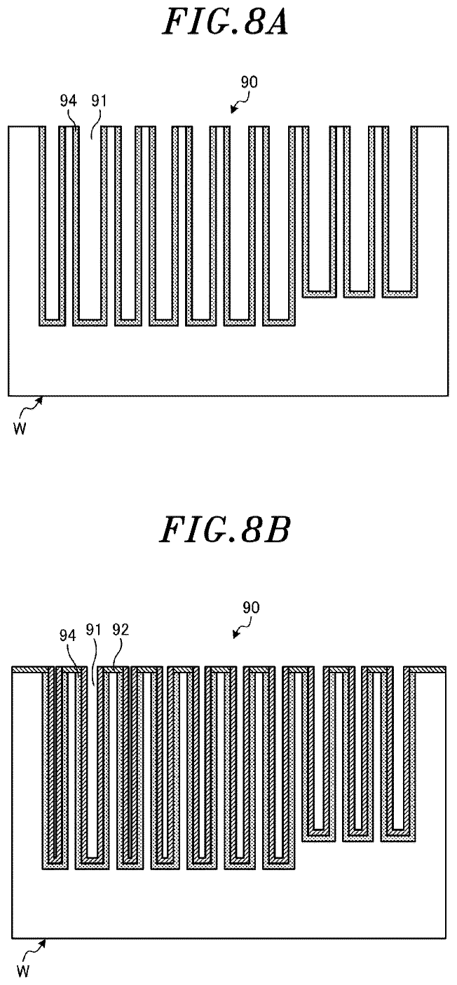

FIGS. 8A and 8B show an example of the substrate W according to the first embodiment. FIG. 8A shows the substrate W before film formation. The pattern 90 including the recesses 91 is formed on the substrate W. A film 94 is formed in the recesses 91. FIG. 8B shows a state in which the film 92 is formed on the substrate W. FIG. 8B shows a state in which the recesses 91 are being filled with the film 92, and the recesses 91 are not yet filled with the film 92. The film 92 is a target film to be processed for determining the embedded state.

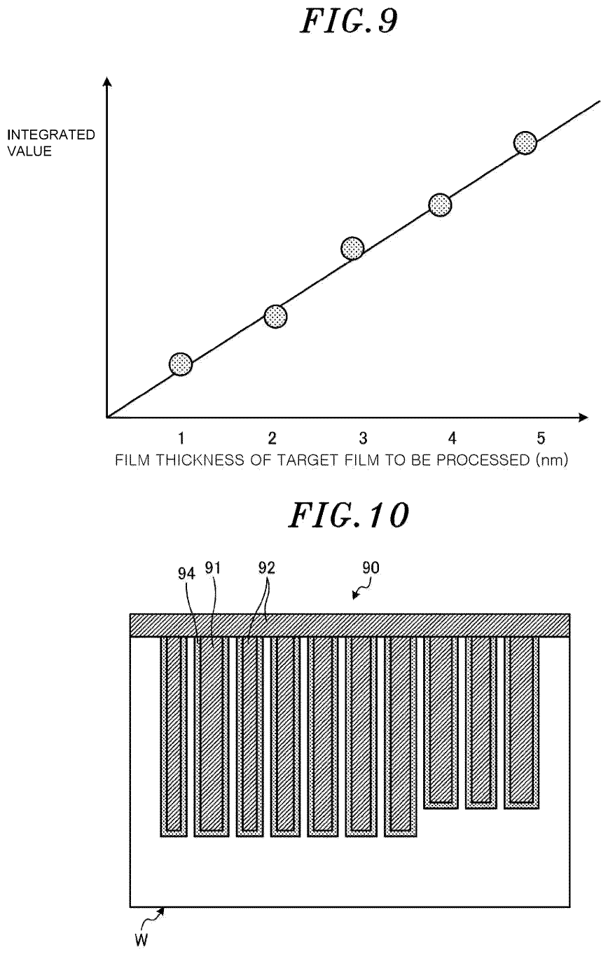

FIG. 9 shows an example of relationship between an integrated value of an absorbance spectrum and a film thickness of a formed film according to the first embodiment. FIG. 9 shows the relationship between the integrated value of the intensity of the absorbance spectrum in a predetermined wavenumber range and the film thickness of the target film (the film 92) to be processed formed on the substrate W in which the recesses 91 are not filled with the film 92. When the recesses 91 are not filled with the film 92, there is a proportional relationship between the integrated value of the absorbance spectrum and the thickness of the film 92, as shown in FIG. 9.

FIG. 10 shows an example of the substrate W according to the first embodiment. FIG. 10 shows a state in which a film is further formed on the substrate W of FIG. 8B. When a film is further formed on the substrate W of FIG. 8B, the recesses 91 are filled with the film 92 as shown in FIG. 10, so that the film 92 is formed on the entire surface of the substrate W.

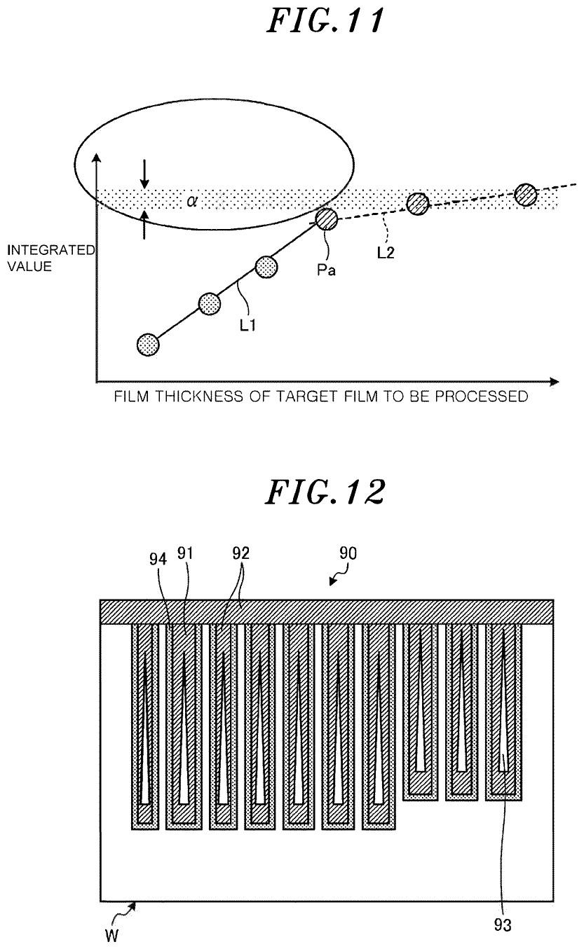

FIG. 11 shows an example of relationship between an integrated value of an absorbance spectrum and a film thickness of a formed film according to the first embodiment. FIG. 11 shows the relationship between the integrated value of the intensity of the absorbance spectrum in a predetermined wavenumber range and the target film to be processed (the film 92) formed on the substrate W in which the recesses 91 are filled with the film 92 after FIG. 9. A line L1 shows the relationship between the integrated value and the film thickness when the recesses 91 are not filled with the film 92. A line L2 shows the relationship between the integrated value and the film thickness when the recesses 91 are filled with the film 92. When the recesses 91 are filled with the film 92, the inclination of the proportional relationship changes. For example, the inclinations of the lines L1 and L2 change at a change point Pa, and the inclination of the line L2 is smaller than that of the line L1.

FIG. 12 shows an example of the substrate W according to the first embodiment. FIG. 12 shows a state in which a film is further formed on the substrate W in FIG. 8B, but voids 93 have occurred in the recesses 91. As shown in FIG. 12, when the voids 93 have occurred in the recesses 91, the spaces in the voids 93 are not filled with the film 92, so that the film 92 quickly reaches the upper portions of the recesses 91 and is quickly formed on the surface of the substrate W compared to when the recesses 91 are filled with the film 92 as shown in FIG. 10B.

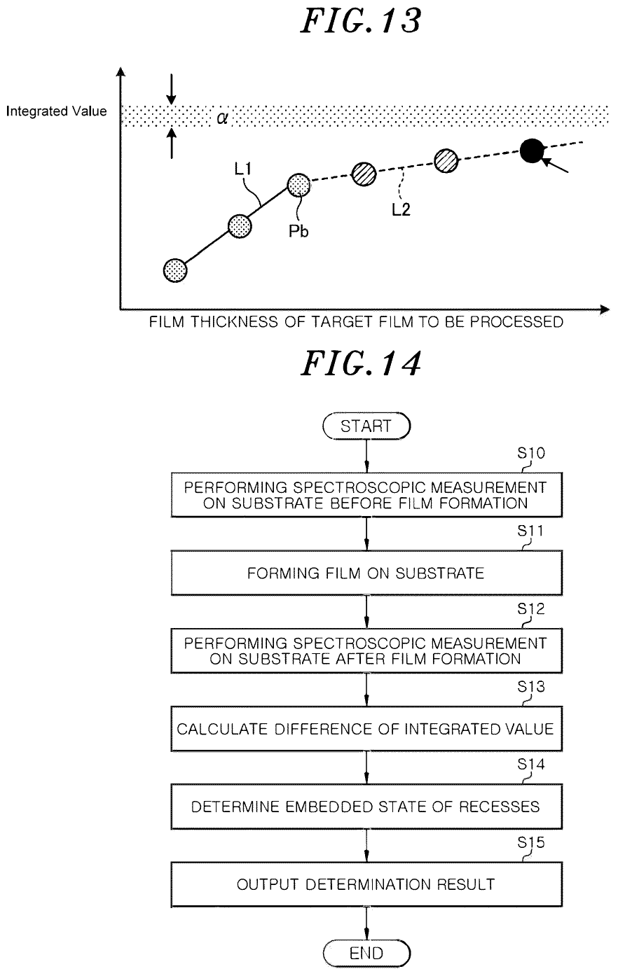

FIG. 13 shows an example of relationship between an integrated value of an absorbance spectrum and a film thickness of a formed film according to the first embodiment. FIG. 13 shows the relationship between the integrated value of the intensity of the absorbance spectrum in a predetermined wavenumber range and the film thickness of the film 92 formed on the substrate W in the case where the voids 93 have occurred formed in the recesses 91 as shown in FIG. 12. The line L1 shows the relationship between the integrated value and the film thickness in a state where the recesses 91 are not filled with the film 92. The line L2 shows the relationship between the integrated value and the film thickness in a state where the recesses 91 are filled with the film 92. When the voids 93 have occurred in the recesses 91, the recesses 91 are quickly filled with the film 92. Therefore, a change point Pb at which the inclination of the proportional relationship changes appears earlier than the change point Pa shown in FIG. 11. As a result, the integrated value of the absorbance spectrum changes between when the voids 93 have occurred in the recesses 91 and when the voids 93 have not occurred in the recesses 91. For example, the integrated value of the absorbance spectrum is smaller when the voids 93 have occurred in the recesses 91 than when the voids 93 have not occurred. Accordingly, whether or not the voids 93 have occurred in the recesses 91 can be determined from the integrated value of the absorbance spectrum.

The controller 60 determines the embedded state of the recesses 91 based on the calculated integrated value. For example, the controller 60 determines whether or not the voids 93 have occurred in the recesses 91 based on whether or not the calculated integrated value is within a predetermined tolerance range. FIGS. 11 and 13 show a tolerance range α. In the case of FIG. 11, the integrated value is within the tolerance range α, so that it is determined that the voids 93 have not occurred and, thus, embedding defects have not occurred. On the other hand, in the case of FIG. 13, the integrated value is smaller than the tolerance range α, so that it is determined that the voids 93 have occurred and, thus, embedding defects have occurred.

Further, the controller 60 may determine whether or not the voids 93 have occurred in the recesses 91 based on whether the calculated integrated value is greater than or equal to a predetermined threshold.

The tolerance range or the threshold is specified in advance by a test or a simulation. For example, the film forming apparatus 100 according to the first embodiment performs film formation for filling the recesses 91 on the actual substrate W. The film forming apparatus 100 performs spectroscopic measurement on the substrate W after film formation to measure the absorbance spectrum of the substrate W after film formation in which the recesses 91 are filled. Further, the film forming apparatus 100 obtains the integrated value of the intensity of the absorbance spectrum in a predetermined wavenumber range of the measured absorbance spectrum of the substrate W. Further, the substrate W after film formation is taken out from the film forming apparatus 100 and analyzed to determine whether or not the voids 93 have occurred in the recesses 91. The integrated value of the absorbance spectrum in the case where the voids 93 have occurred and the integrated value of the absorbance spectrum in the case where the voids 93 have not occurred are specified. The tolerance range and the threshold are determined such that the integrated value in the case where the voids 93 have not occurred in the recesses 91 is included in the range and the integrated value in the case where the void 93 have occurred in the recesses 91 is not within the range.

In the first embodiment, the state of the film formed on the substrate W is detected based on the spectroscopic measurement result of the substrate W after film formation when the spectroscopic measurement is performed on the substrate W after film formation. However, the present disclosure is not limited thereto. The film forming apparatus 100 according to the first embodiment may perform the spectroscopic measurement on the substrate W before film formation and the substrate W after film formation, and detect the state of the film formed on the substrate W based on the spectroscopic measurement results of the substrate W before film formation and the substrate W after film formation. For example, the film forming apparatus 100 performs the spectroscopic measurement on the substrate W before film formation to measure the absorbance spectrum of the substrate W before the embedding material is embedded. The film forming apparatus 100 forms a film on the substrate W to fill the recesses 91 with the embedding material. The SiO film or the SiN film as an embedding material may be a film containing impurities such as carbon, boron, or fluorine. The film forming apparatus 100 performs spectroscopic measurement on the substrate W after film formation to measure the absorbance spectrum of the substrate W in which the embedding material is embedded. The film forming apparatus 100 may determine the embedded state of the recesses 91 based on the difference between the integrated value of the intensity of the absorbance spectrum of the substrate W before the embedding material is embedded in the recesses 91 at a plurality of wavenumbers and the integrated value of the intensity of the absorbance spectrum of the substrate W in which the embedding material is embedded in the recesses 91 at a plurality of wavenumbers.

Next, the flow of substrate processing including the determination method according to the first embodiment will be described. Hereinafter, the flow of performing spectroscopic measurement on the substrate W before film formation and the substrate W after film formation, and detecting a state of the film formed on the substrate W based on the spectroscopic measurement results of the substrate W before film formation and the substrate W after film formation will be described. FIG. 14 is a flowchart showing an example of the flow of substrate processing according to the first embodiment.

First, the spectroscopic measurement is performed on the substrate W before film formation to measure the absorbance spectrum of the substrate W before the embedding material is embedded (step S10). For example, the substrate W on which the pattern 90 including the recesses 91 is formed is placed on the placing table 2. In the film forming apparatus 100, the controller 60 controls the irradiator 81 to irradiate infrared light to the substrate W, before film formation, and the transmitted light that has transmitted through the substrate W is detected by the detector 82.

Next, a film is formed on the substrate W using thermal CVD, thermal ALD, PE-CVD, PE-ALD, or the like (step S11). For example, the controller 60 controls the gas supply source 15 and the RF power supply 10 to form the film 92 on the surface of the substrate W.

Next, the spectroscopic measurement is performed on the substrate W after film formation to measure the absorbance spectrum of the substrate W in which the embedding material is embedded (step S12). For example, in the film forming apparatus 100, the controller 60 controls the irradiator 81 to irradiate infrared light to the substrate W, after film formation, and the transmitted light that has transmitted through the substrate W or the reflected light is detected by the detector 82.

Next, the difference between the integrated value of the intensity at a plurality of wavenumbers of the absorbance spectrum of the transmitted light or the reflected light of the substrate W before film formation measured in step S10 and the integrated value of the intensity at a plurality of wavenumbers of the absorbance spectrum of the transmitted light or the reflected light of the substrate W after film formation measured in step S12 is calculated (step S13). For example, the controller 60 obtains the absorbance spectrum of the transmitted light or the reflected light of the substrate W before film formation from the data detected by the detector 82 in step S10, and calculates the integrated value of the intensity of the absorbance spectrum for a predetermined wavenumber range. Further, the controller 60 obtains the absorbance spectrum of the transmitted light or the reflected light of the substrate W after film formation from the data detected by the detector 82 in step S12, and calculates the integrated value of the intensity of the absorbance spectrum for a predetermined wavenumber range. The controller 60 subtracts the integrated value of the substrate W before film formation from the integrated value of the substrate W after film formation to calculate the integrated value of the difference. By subtracting the integrated value of the spectrum of the transmitted light or the reflected light before film formation from the integrated value of the spectrum of the transmitted light or the reflected light after film formation, the integrated value of the absorbance spectrum of the film 92 can be extracted as the difference.

Next, the embedded state of the recesses 91 is determined based on the integrated value of the calculated difference (step S14). For example, the controller 60 determines the embedded state of the recesses 91 based on the integrated value of the difference. For example, the controller 60 determines whether or not the voids 93 have occurred in the recesses 91 based on whether or not the integrated value of the difference is within a predetermined tolerance range or is greater than or equal to a predetermined threshold.

The determination result is outputted (step S15), and the processing is ended. For example, the controller 60 transmits the data of the determination result to an external device such as a management device that can communicate via a network (not shown). Further, the controller 60 displays the determination result on the display part of the user interface 61. Accordingly, a process manager can recognize whether or not embedding defects have occurred in the substrate W on which the film is formed. When the embedding defects have occurred, the process manager stops the processing in which the embedding defects have occurred, and instructs scrapping of substrates W in the lot including the substrate W where the embedding defects have occurred or investigation of device malfunction.

Here, an example of a specific determination result will be described. As a test example, the integrated value of the intensity of the absorbance spectrum of a sample in which a SiN film is embedded in each of a plurality of substrates on which a step-shaped pattern such as Line and Space is formed thereon by an ALD method was calculated. FIG. 15 shows an example of the substrate W as a sample. The pattern 90 including the recesses 91 is formed on the substrate W, and the recesses 91 are filled with an SiN film 92a. The recess 91 has an opening space width of 50 nm and a depth of 290 nm, for example.

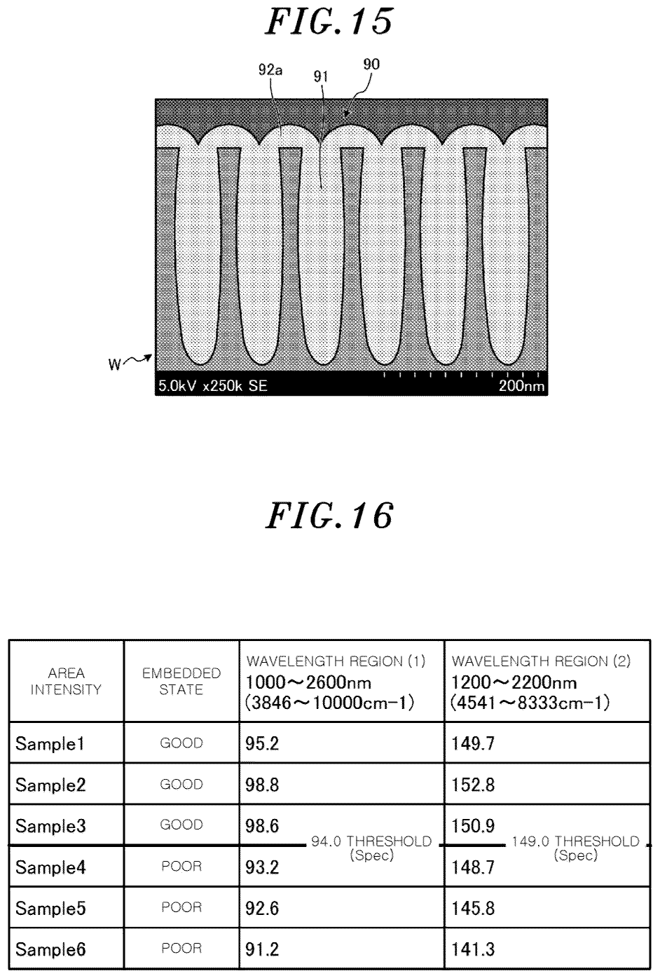

FIG. 16 shows an example of the integrated value of the intensity of the absorbance spectrum of each sample. In FIG. 16, the substrates W as samples are indicated as “Sample 1” to “Sample 6.” Further, FIG. 16 shows, as the embedded state, the state of occurrence of embedding defects such as the voids 93 in “Sample 1” to “Sample 6.” Further, FIG. 16 shows the calculation results of the integrated value of the intensity of the absorbance spectrum for wavelength regions (1) and (2) of “Sample 1” to “Sample 6.” The wavelength region (1) is within a range of 1000 nm to 2600 nm (3846 cm⁻¹ to 10000 cm⁻¹). The wavelength region (2) is within a range of 1200 nm to 2200 nm (4541 cm⁻¹ to 8333 cm⁻¹). “Sample 1” to “Sample 3” have no embedding defects such as the voids 93, and have a good embedded state. On the other hand, “Sample 4” to “Sample 6” have embedding defects such as the voids 93, and have a poor embedded state. The integrated values of the wavelength regions (1) and (2) are smaller in “Sample 4” to “Sample 6” in which the embedded state is poor than in “Sample 1” to “Sample 3” in which the embedded state is good. Therefore, by setting the threshold to 94.0 for the wavelength region (1), for example, whether the embedded state is good or poor can be determined by the integrated value of wavelength region (1). Further, by setting the threshold to 149.0 for the wavelength region (2), for example, whether the embedded state is good or poor can be determined by the integrated value of the wavelength region (2).

As described above, the determination method according to the first embodiment includes a post-embedding measurement step of performing spectroscopic measurement on the substrate in which the pattern 90 including the recesses 91 are formed, the recesses 91 having an embedding material embedded therein, and measuring the absorbance spectrum of the substrate W having the embedding material embedded therein (step S12), and a determination step for determining the embedded state of the recesses 91 based on the integrated value of the intensity of the measured absorbance spectrum of the substrate at a plurality of wavenumbers (steps S13 and S14). Accordingly, the determination method according to the first embodiment can detect the occurrence of embedding defects.

Further, on the substrate W, the pattern 90 is formed in each region 95 that will become a chip. The spot size of the measurement light in the spectroscopic measurement is larger than the chip. Accordingly, the determination method according to the first embodiment can detect the embedded state of the entire pattern 90 in the region 95 without highly accurate alignment.

In the determination method according to the first embodiment, the embedded state of the recesses 91 is determined based on the integrated value of the intensity of the absorbance spectrum in a predetermined wavenumber range including the wavenumber at which a peak occurs due to the embedding material in the absorbance spectrum of the substrate W. Accordingly, the determination method according to the first embodiment can detect the occurrence of embedding defects of the embedding material.

The determination method according to the first embodiment determines whether or not the voids exist in the recesses 91 in which the embedding material is embedded based on whether or not the integrated value is within a predetermined range or is greater than or equal to a predetermined threshold. Accordingly, the determination method according to the first embodiment can detect whether or not the voids 91 exist in the recesses 91.

In the determination method according to the first embodiment, in the spectroscopic measurement, light is irradiated onto the substrate W, and the light that has transmitted through the substrate W or the reflected light is detected. Accordingly, the determination method according to the first embodiment can detect the occurrence of embedding defects in the recesses 91 even when the recesses 91 have a large depth.

The substrate W may be a silicon substrate. In the spectroscopic measurement, infrared light is irradiated onto the substrate W, and the infrared light that has transmitted through the substrate W or the reflected infrared light is detected. Accordingly, the determination method according to the first embodiment can detect the occurrence of embedding defects in the recesses 91 formed in the silicon substrate.

The determination method according to the first embodiment further includes a step of performing spectroscopic measurement on the substrate W before the embedding material is embedded in the recesses 91 and measuring the absorbance spectrum of the substrate W before the embedding material is embedded (step S10), and a step of filling the embedding material in the recesses 91 (step S11). The determination method according to the first embodiment determines the embedded state of the recesses 91 based on the difference between the integrated value of the intensity at a plurality of wavenumbers of the absorbance spectrum of the substrate W before the embedding material is embedded in the recesses 91 and the integrated value of the intensity at a plurality of wavenumbers of the absorbance spectrum of the substrate W in which the embedding material is embedded in the recesses 91. Accordingly, in the determination method according to the first embodiment, the integrated value of the absorbance spectrum of the embedding material can be extracted as the difference and, thus, the occurrence of embedding defects of the embedding material can be detected with high precision.

### Second Embodiment

Next, a second embodiment will be described.

In the spectroscopic measurement, measurement errors may occur due to environmental factors or the like. For example, when the amount of infrared light irradiated by the irradiator 81 changes, the measurement errors occur in the spectroscopic measurement result.

Therefore, in the second embodiment, a technique for suppressing measurement errors will be described. Since the film forming apparatus 100 according to the second embodiment has the same configuration as that of the first embodiment shown in FIGS. 1 to 3, the description of the same parts will be omitted and differences will be mainly described.

The film forming apparatus 100 according to the second embodiment is configured to be able to change the irradiation position of light incident on the substrate W from the irradiator 81. For example, in the film forming apparatus 100 according to the second embodiment, the irradiator 81 and the detector 82 are configured to be movable and rotatable by a driving mechanism (not shown), so that the irradiation position of light incident on the substrate W can be changed. Further, for example, in the film forming apparatus 100 according to the second embodiment, the placing table 2 or the substrate W are configured to be movable by a driving mechanism (not shown), so that the irradiation position of light incident on the substrate W can be changed.

In the second embodiment, the spectroscopic measurement is performed on the first region of the substrate W in which the pattern 90 is formed and the second region of the substrate W in which the number of recesses 91 is smaller than that in the first region to measure the absorbance spectrum of the first region and the absorbance spectrum of the second region. Further, in the second embodiment, the embedded state of the recesses 91 in the first region is determined based on the difference between the integrated value of the intensity of the absorbance spectrum of the first region at a plurality of wavenumbers and the integrated value of the intensity of the absorbance spectrum of the second region at a plurality of wavenumbers.

The second region is a region of the substrate W that is considered to be flat. For example, in the second region, the ratio of the area of the recesses 91 is preferably 50% or less, and more preferably 30% or less. Alternatively, in the second region, the area of the recesses 91 is preferably 50% or less compared to the first region, and more preferably 30% or less compared to the first region.

The second region may be a boundary region of regions of the substrate W that will become chips. For example, on the substrate W, the pattern 90 is formed to correspond to the regions that will become chips of a semiconductor device, and a region of the scribe lines SL for dividing the substrate W into chips is formed around the regions that will become chips. The second region may be the region of the scribe lines SL.

The second region is preferably located near the first region. For example, the second region is a region of the scribe lines SL near the first region. Accordingly, the absorbance spectrum can be measured in a state where the second region and the first region have the same film formation state.

Further, the second region may be disposed as a dedicated region on the substrate W. For example, the second region may be disposed in a region where a chip is not formed, such as the outer edge of the substrate W.

In the film forming apparatus 100 according to the second embodiment, the infrared light is irradiated from the irradiator 81 to the first region of the substrate W, and the infrared light that has transmitted through the substrate W or the reflected infrared light is detected by the detector 82. The film forming apparatus 100 measures the absorbance spectrum indicating the absorbance of the first region of the substrate W from the infrared light detected by the detector 82. For example, the controller 60 measures the absorbance spectrum of the first region of the substrate W by obtaining the absorbance for each wavenumber from the signal intensity data detected by the detector 82.

Further, the film forming apparatus 100 moves the irradiator 81 to an irradiation position where the infrared light is incident on the second region of the substrate W, irradiates the infrared light from the irradiator 81 to the second region of the substrate W, and detects the infrared light that has passed through or been reflected by the substrate W with the detector 82. In the film forming apparatus 100, the absorbance spectrum indicating the absorbance of the infrared light in the second region of the substrate W is measured by obtaining the absorbance for each wavenumber from the infrared light detected by the detector 82. For example, the controller 60 measures the absorbance spectrum of the second region of the substrate W by obtaining the absorbance for each wavenumber from the signal intensity data detected by the detector 82.

The film forming apparatus 100 determines the embedded state of the recesses 91 based on the difference between the integrated value of the intensity at a plurality of wavenumbers of the absorbance spectrum of the first region of the substrate W and the integrated value of the intensity at a plurality of wavenumbers of the absorbance spectrum of the second region of the substrate W. For example, the controller 60 calculates the integrated value of the intensity for the same predetermined wavenumber range from the absorbance spectrum of the first region of the substrate W and the absorbance spectrum of the second region of the substrate W. The controller 60 determines the embedded state of the recesses 91 based on the difference between the integrated value calculated from the absorbance spectrum of the first region of the substrate W and the integrated value calculated from the absorbance spectrum of the second region of the substrate W.

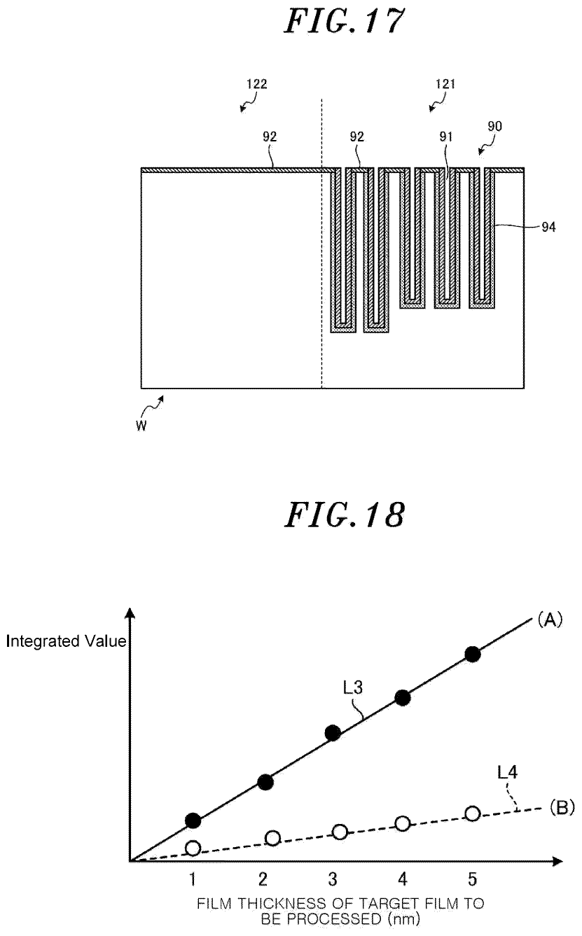

FIG. 17 shows an example of a substrate W according to the second embodiment. FIG. 17 shows a first region 121 in which the pattern 90 of the substrate W is formed, and a second region 122 in which the number of recesses 91 is smaller than that in the first region 121. In the first region 121 of the substrate W, the pattern 90 including the recesses 91 is formed. The film 94 is formed in the recesses 91, and the film 92 is formed. The recesses 91 are not filled with the film 92. The second region 122 of the substrate W has a flat surface without the recess 91, and the film 92 is formed on the surface.

FIG. 18 shows an example of relationship between an integrated value of an absorbance spectrum and a film thickness of a formed film according to the second embodiment. FIG. 18 shows the relationship between the integrated value of the intensity of the absorbance spectrum in a predetermined wavenumber range and the film thickness of the target film to be processed (the film 92) formed on the substrate W in which the recesses 91 are not filled with the film 92. A line L3 indicates a change in an integrated value (A) of the absorbance spectrum of the first region 121. A line L4 indicates a change in an integrated value (B) of the absorbance spectrum of the second region 122. The inclination of the line L3 is different from that of the line L4 when the recesses 91 of the first region 121 are not filled with the film 92.

Here, in the spectroscopic measurement, measurement errors may occur due to environmental factors or the like. The environmental factors that cause measurement errors may include, e.g., a temperature, a humidity, the amount of light from a light source, and deviation of a measurement position. For example, when the amount of infrared light irradiated by the irradiator 81 changes, measurement errors occur in the spectroscopic measurement result.

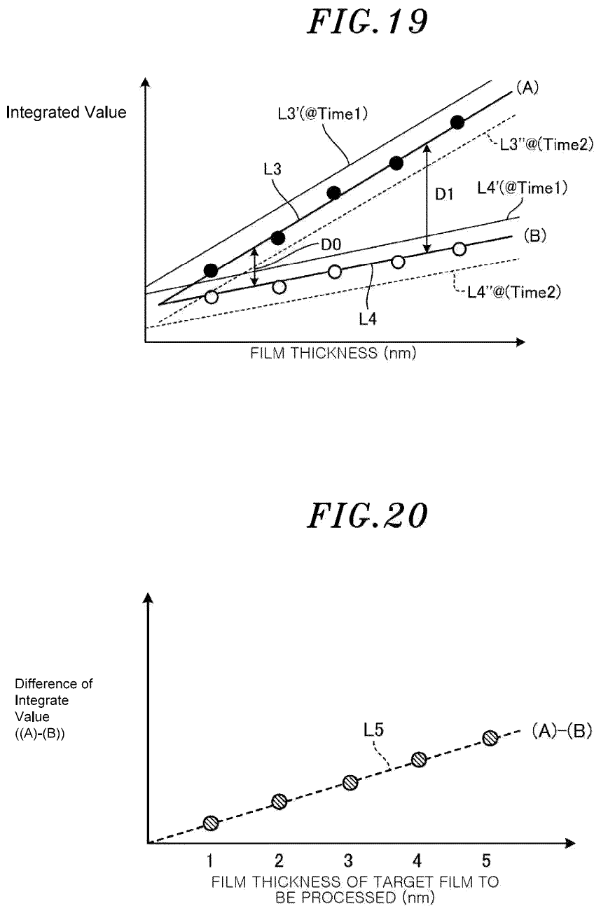

FIG. 19 shows an example of relationship between an integrated value of an absorbance spectrum and a film thickness of a formed film according to the second embodiment. FIG. 19 shows an example of a change in the relationship between an integrated value of an absorbance spectrum and a film thickness of a film due to environmental factors. The line L3 indicates a change in the integrated value (A) of the absorbance spectrum of the first region 121. The line L4 indicates a change in the integrated value (B) of the absorbance spectrum of the second region 122. The lines L3 and L4 are entirely shifted due to the change in the environmental error factors. For example, due to the change in the environmental error factors such as the amount of infrared light irradiated by the irradiator 81, the lines L3 and L4 are changed to lines L3′ and L4′ at a certain first time point (@Time1). Further, the line L3 and L4 are changed to lines L3″ and L4″ at a certain second time point (@Time2). Here, the change in the environmental error factors is mainly the component of the shift of the lines L3 and L4. A difference D0 or D1 between the line L3 and the line L4 is less affected by the change in the environmental error factors.

Therefore, in the second embodiment, the embedded state of the recesses 91 is determined based on the difference between the integrated value (A) of the intensity at a plurality of wavenumbers of the absorbance spectrum of the first region 121 of the substrate W and the integrated value (B) of the intensity at a plurality of wavenumbers of the absorbance spectrum of the second region 122 of the substrate W. For example, the controller 60 calculates the integrated values (A) and (B) of the intensity for the same predetermined wavenumber range from the absorbance spectrum of the first region 121 of the substrate W and the absorbance spectrum of the second region 122 of the substrate W. The controller 60 determines the embedded state of the recesses 91 based on the difference between the integrated value (A) of the absorbance spectrum of the first region 121 of the substrate W and the integrated value (B) of the absorbance spectrum of the second region 122.

FIG. 20 shows an example of relationship between the difference and a film thickness of a formed film according to the second embodiment. FIG. 20 shows the result of the relationship between the film thickness of the target film (the film 82) to be processed formed on the substrate W in which the recesses 91 are not filled with the film 92 and the difference (the integrated value (A)-the integrated value (B)) between the integrated value (A) of the absorbance spectrum of the first region 121 of the substrate W and the integrated value (B) of the absorbance spectrum of the second region 122 of the substrate W. A line L5 shows a change in the difference (the integrated value (A)-the integrated value (B)). When the recesses 91 are not filled with the film 92, there is a proportional relationship between the difference between the integrated value (A) and the integrated value (B) and the film thickness of the film 92, as indicated by the line L5.

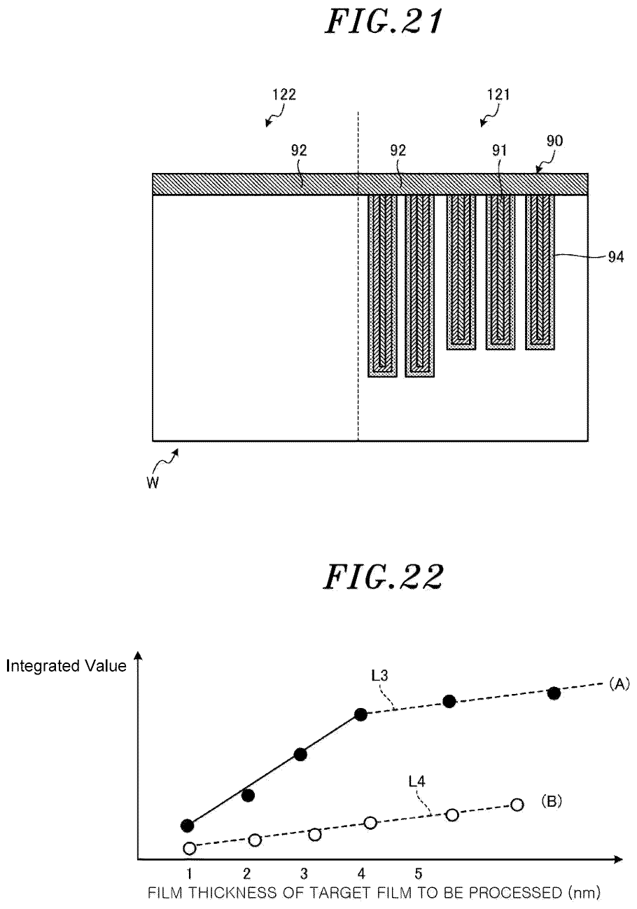

FIG. 21 shows an example of the substrate W according to the second embodiment. FIG. 21 shows a state in which a film is further formed on the substrate W of FIG. 17. FIG. 21 shows the first region 121 and the second region 122 in which the pattern 90 of the substrate W is formed. When a film is further formed on the substrate W of FIG. 17, the recesses 91 are filled with the film 92 as shown in FIG. 21, and the film 92 is formed on the surfaces of the first region 121 and the second region 122 of the substrate W.

FIG. 22 shows an example of relationship between an integrated value of an absorbance spectrum and a film thickness of a formed film according to the second embodiment. FIG. 22 shows the result of the relationship between the integrated value of the intensity of the absorbance spectrum in a predetermined wavenumber range and the film thickness of the target film to be processed (the film 92) formed on the substrate W in which the recesses 91 are filled with the film 92 after FIG. 18. The line L3 indicates a change in the integrated value (A) of the absorbance spectrum of the first region 121. The line L4 indicates a change in the integrated value (B) of the absorbance spectrum of the second region 122. When the recesses 91 are filled with the film 92, the film 92 is also formed on the surface of the second region 122, so that the change in the inclination of the line L3 is substantially the same as the change in the inclination of the line L4.

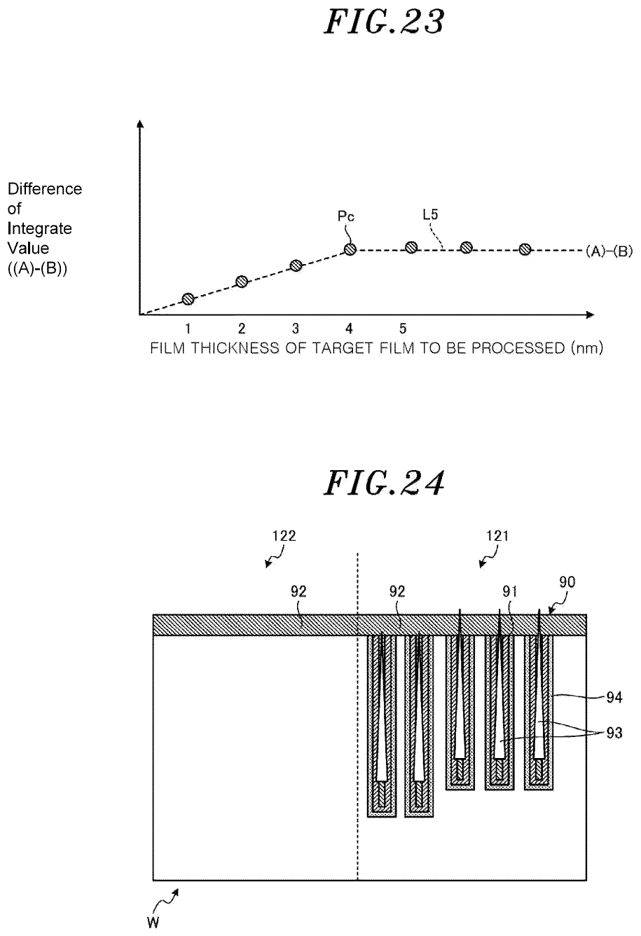

FIG. 23 shows an example of relationship between the difference and a film thickness of a formed film according to the second embodiment. FIG. 23 shows the result of the relationship between the film thickness of the target film to be processed (the film 92) formed on the substrate W in which the recesses 91 are filled with the film 92 and the difference between the integrated value (A) and the integrated value (B). The line L5 shows a change in the difference (the integrated value (A)-the integrated value (B)). As shown in FIG. 22, when the recesses 91 are filled with the film 92, the change in the inclination of the line L3 is substantially the same as the change in the inclination of the line L4. Therefore, when the recesses 91 are filled with the film 92, the difference between the integrated value (A) and the integrated value (B) becomes a substantially constant value. For example, as indicated by the line L5, the difference between the integrated value (A) and the integrated value (B) changes in inclination at the change point Pc, and becomes a substantially constant value.

FIG. 24 shows an example of the substrate W according to the second embodiment. FIG. 24 shows the first region 121 in which the pattern 90 of the substrate W is formed, and the second region 122. FIG. 24 shows a state in which a film is further formed on the substrate W of FIG. 17, but the voids 93 have occurred in the recesses 91. As shown in FIG. 24, when the voids 93 have occurred in the recesses 91, the spaces of the voids 93 are not filled with the film 92. Hence, the formation of the film 92 at the upper parts of the recesses 91 starts earlier, and in the first region 121, the film 92 is formed on the surface of the substrate W earlier than when the recesses 91 are filled with the film 92 as shown in FIG. 21.

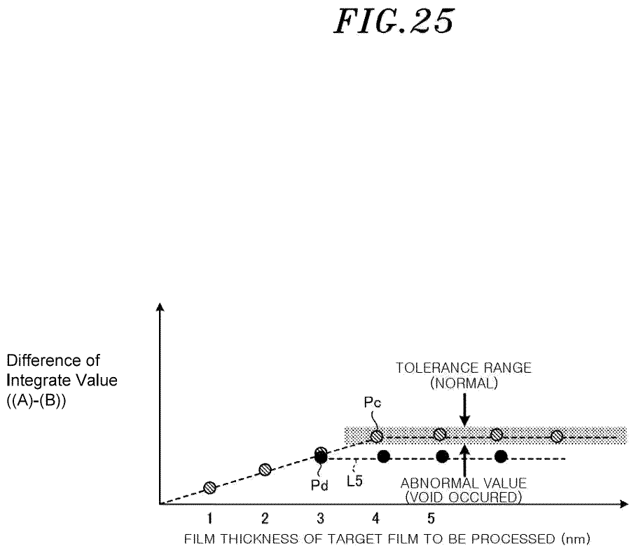

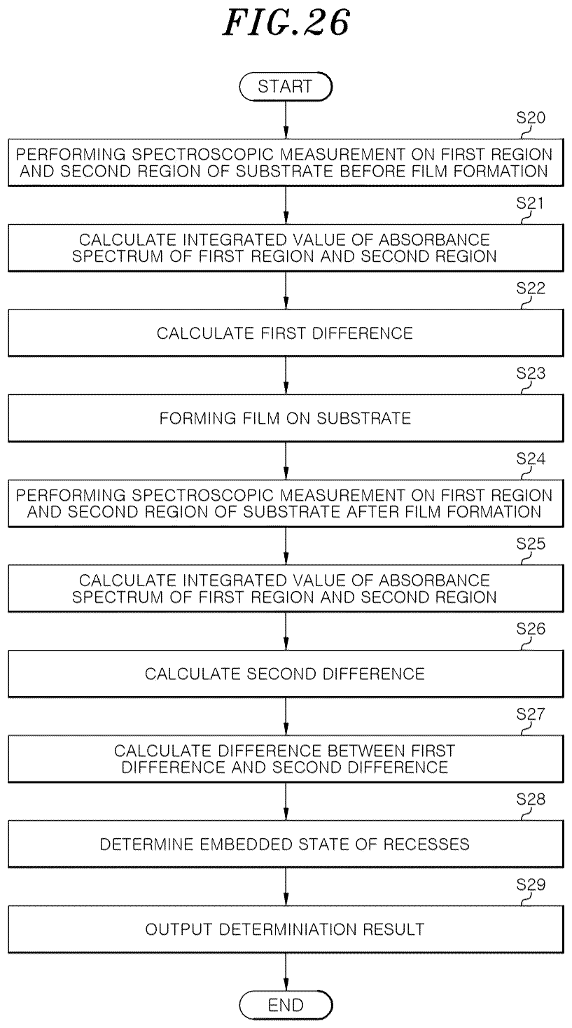

FIG. 25 shows an example of relationship between an integrated value of an absorbance spectrum and a film thickness of a formed film according to the second embodiment. FIG. 25 shows the result of the relationship between the difference between the integrated value (A) and the integrated value (B) and the film thickness of the target film to be processed (the film 92) formed on the substrate W in which the voids 93 have occurred in the recesses 91 as shown in FIG. 24. When the voids 93 have occurred in the recesses 91, the recesses 91 are quickly filled with the film 92. Therefore, a change point Pd at which the inclination of the difference between the integrated value (A) and the integrated value (B) changes appears earlier than the change point Pc shown in FIG. 23. As a result, the difference between the integrated value (A) and the integrated value (B) changes depending on whether the voids 93 have occurred in the recesses 91 or the voids 93 have not occurred in the recesses 91. For example, the difference between the integrated value (A) and the integrated value (B) is smaller when the voids 93 have occurred in the recesses 91 than when the voids 93 have not occurred. Hence, whether or not the voids 93 has occurred in the recesses 91 can be determined from the integrated value of the absorbance spectrum.

The controller 60 determines the embedded state of the recesses 91 based on the difference between the integrated value (A) of the absorbance spectrum of the first region 121 of the substrate W and the integrated value (B) of the absorbance spectrum of the second region 122. For example, the controller 60 determines whether or not the voids 93 have occurred in the recesses 91 based on whether or not the difference between the integrated value (A) and the integrated value (B) is within a predetermined tolerance range. FIG. 25 shows a tolerance range B. When the difference between the integrated value (A) and the integrated value (B) is within the tolerance range B, the controller 60 determines that the voids 93 have not occurred and, thus, embedding defects have not occurred. On the other hand, when the difference between the integrated value (A) and the integrated value (B) is smaller than the tolerance range B, the controller 60 determines that the voids 93 have occurred and, thus, embedding defects have occurred.

Further, the controller 60 may determine whether or not the voids 93 has occurred in the recesses 91 based on whether or not the difference between the integrated value (A) and the integrated value (B) is greater than or equal to a predetermined threshold.

The tolerance range or the threshold are specified in advance by a test or a simulation. For example, the film forming apparatus 100 according to the second embodiment performs film formation for filling the recesses 91 on the actual substrate W. The film forming apparatus 100 performs spectroscopic measurement on the first region 121 in which the pattern 90 of the substrate W after film formation is formed, and the second region 122 in which the number of recesses 91 is smaller than that in the first region 121 to measure the absorbance spectrum of the first region 121 and the absorbance spectrum of the second region 122 of the substrate W after film formation in which the recesses 91 are filled. Then, the film forming apparatus 100 obtains the integrated value (A) and the integrated value (B) of the intensity of the absorbance spectrum in a predetermined wavenumber range of the measured absorbance spectra of the first region 121 and the second region 122 of the substrate W. Further, the substrate W after film formation is taken out from the film forming apparatus 100 and is analyzed to determine whether or not the voids 93 have occurred in the recesses 91, and the integrated value of the absorbance spectrum in the case where the voids 93 have occurred in the recesses 91 and the integrated value of the absorbance spectrum in the case where the voids 93 have not occurred in the recesses 91 are specified. Further, the tolerance range or the threshold is determined such that the difference between the integrated value (A) and the integrated value (B) in the case where the voids 93 have not occurred in the recesses 91 is within the range, and the difference between the integrated value (A) and the integrated value in the case where the voids 93 have occurred in the recesses 91 is not within the range.

In the above-described second embodiment, the case in which the spectroscopic measurement is performed on the first region 121 and the second region 122 of the substrate W after film formation, and the state of the film formed on the substrate W is detected based on the spectroscopic measurement results of the first region 121 and the second region 122 of the substrate W after film formation has been described. However, the present disclosure is not limited thereto. The film forming apparatus 100 according to the second embodiment may perform the spectroscopic measurement on the first region 121 and the second region 122 of both the substrate W before film formation and the substrate W after film formation, and detect the states of the films formed on the substrates W based on the spectroscopic measurements of the substrate W before film formation and the substrate W after film formation. For example, the film forming apparatus 100 performs the spectroscopic measurement on the first region 121 and the second region 122 of the substrate W before film formation to measure the absorbance spectrum of the first region 121 and the second region 122 of the substrate W before the embedding material is embedded. The film forming apparatus 100 calculates the integrated value (A) and the integrated value (B) of the intensity for the same predetermined wavenumber range from the absorbance spectrum of the first region 121 of the substrate W and the absorbance spectrum of the second region 122 of the substrate W. The film forming apparatus 100 calculates a first difference that is the difference between the integrated value (A) of the absorbance spectrum of the first region 121 of the substrate W and the integrated value (B) of the absorbance spectrum of the second region 122 of the substrate W. The film forming apparatus 100 performs film formation on the substrate W to fill the embedding material in the recesses 91. The film forming apparatus 100 performs the spectroscopic measurement on the first region 121 and the second region 122 of the substrate W after film formation to measure the absorbance spectrum of the first region 121 and the second region 122 of the substrate W in which the embedding material is embedded. The film forming apparatus 100 calculates the integrated value (A) and the integrated value (B) of the intensity for the same predetermined wavenumber range as that before film formation from the absorbance spectrum of the first region 121 of the substrate W and the absorbance spectrum of the second region 122 of the substrate W. The film forming apparatus 100 calculates a second difference that is the difference between the integrated value (A) of the absorbance spectrum of the first region 121 of the substrate W and the integrated value (B) of the absorbance spectrum of the second region 122 of the substrate W. The film forming apparatus 100 may determine the embedded state of the recesses 91 based on the difference between the first difference obtained from the substrate W before the recesses 91 are filled with the embedding material and the second difference obtained from the substrate W in which the recesses 91 are filled with the embedding material.

Next, the flow of substrate processing including the determination method according to the second embodiment will be described. Hereinafter, the flow of the case in which the spectroscopic measurement is performed on the first region 121 and the second region 122 of both the substrate W before film formation and the substrate W after film formation, and the states of the films formed on the substrates W are detected based on the spectroscopic measurement results of the substrate W before film formation and the substrate W after film formation will be described. FIG. 26 is a flowchart showing an example of the flow of substrate processing according to the second embodiment.

First, the spectroscopic measurement is performed on the first region 121 and the second region 122 of the substrate W before film formation, and the absorbance spectra of the first region 121 and the second region 122 of the substrate W before the embedding material is embedded are measured (step S20). For example, the substrate W on which the pattern 90 including the recesses 91 is formed is placed on the placing table 2. In the film forming apparatus 100, infrared light is irradiated from the irradiator 81 to the first region of the substrate W, and the infrared light that has transmitted through the substrate W or the reflected infrared light is detected by the detector 82. Further, the film forming apparatus 100 moves the irradiator 81 to an irradiation position where the infrared light is incident on the second region of the substrate W, irradiates the infrared light from the irradiator 81 to the second region of the substrate W, and detects the infrared light that has passed through or been reflected by the substrate W with the detector 82.

Next, the integrated value of the intensity at a plurality of wavenumbers of the absorbance spectra of the first region 121 and the second region 122 of the substrate W before film formation measured in step S20 is calculated (step S21). For example, the controller 60 obtains the absorbance spectra of the first region 121 and the second region 122 of the substrate W before film formation from the data detected by the detector 82 in step S20. The controller 60 calculates the integrated value of the intensity of the absorbance spectrum for a predetermined wavenumber range from the absorbance spectra of the first region 121 and the second region 122.

Then, the first difference between the integrated value of the absorbance spectrum of the first region 121 of the substrate W before film formation and the integrated value of the absorbance spectrum of the second region 122 of the substrate W before film formation is calculated (step S22). For example, the controller 60 subtracts the integrated value of the absorbance spectrum of the second region 122 from the integrated value of the absorbance spectrum of the first region 121 to calculate the difference as the first difference.

Next, a film is formed on the substrate W using thermal CVD, thermal ALD, PE-CVD, PE-ALD, or the like (step S23). For example, the controller 60 controls the gas supply source 15 and the RF power supply 10 to form the film 92 on the surface of the substrate W.

Next, the spectroscopic measurement is performed on the first region 121 and the second region 122 of the substrate W after film formation to measure the absorbance spectra of the first region 121 and the second region 122 of the substrate W in which the embedding material is embedded (step S24). For example, in the film forming apparatus 100, the irradiator 81 irradiates infrared light to the first region of the substrate W, and the detector 82 detects the infrared light that has transmitted through the substrate W or the reflected infrared light. Further, the film forming apparatus 100 moves the irradiator 81 to an irradiation position where the infrared light is incident on the second region of the substrate W, irradiates the infrared light from the irradiator 81 to the second region of the substrate W, and detects the infrared light that has passed through or been reflected by the substrate W with the detector 82.

Next, the integrated value of the intensity at a plurality of wavenumbers of the absorbance spectra of the first region 121 and the second region 122 of the substrate W after film formation measured in step S24 is calculated (step S25). For example, the controller 60 obtains the absorbance spectra of the first region 121 and the second region 122 of the substrate W after film formation from the data detected by the detector 82 in step S24. The controller 60 calculates the integrated value of the intensity of the absorbance spectrum for the same predetermined wavenumber range as that before film formation from the absorbance spectra of the first region 121 and the second region 122.

Then, the second difference between the integrated value of the absorbance spectrum of the first region 121 of the substrate W after film formation and the integrated value of the absorbance spectrum of the second region 122 of the substrate W after film formation is calculated (step S26). For example, the controller 60 subtracts the integrated value of the absorbance spectrum of the second region 122 from the integrated value of the absorbance spectrum of the first region 121 to calculate the difference as the second difference.

Next, the difference between the first difference calculated in step S22 and the second difference calculated in step S26 is calculated (step S27). For example, the controller 60 subtracts the first difference from the second difference to calculate the difference therebetween. By subtracting the first difference that is the difference before film formation from the second difference that is the difference after film formation, the increase in the integrated value due to the film 92 formed in the process of step S23 is extracted as the difference.

For example, as shown in FIG. 19, the integrated value (A) of the absorbance spectrum of the first region 121 changes as indicated by the line L3, and the integrated value (B) of the absorbance spectrum of the second region 122 changes as indicated by the line L4. For example, the difference D0 is calculated as the first difference. Further, the difference D1 is calculated as the second difference. The lines L3 and L4 are changed to be entirely shifted, similarly to the lines L3′ and L4′ or the lines L3″ and L4″, due to the change in the environmental error factors. Therefore, by obtaining the difference between the line L3 and the line L4, the difference D0 and the difference D1 may be set to a value that does not include errors of the component of the shift. Since the difference is obtained by subtracting the difference D0 from the difference D1, the increase in the integrated value due to the film 92 formed in the process of step S23 can be extracted.

Next, the embedded state of the recesses 91 is determined based on the calculated difference (step S28). For example, the controller 60 determines whether or not the voids 93 have occurred in the recesses 91 based on whether or not the difference is within a predetermined tolerance range or is greater than or equal to a predetermined threshold.

The determination result is outputted (step S29), and the processing is ended. For example, the controller 60 transmits the data of the determination result to an external device such as a management device that can communicate therewith via a network (not shown). Further, the controller 60 displays the determination result on the display part of the user interface 61.

In the determination method according to the second embodiment, the spectroscopic measurement is performed on the first region 121 of the substrate W in which the pattern 90 is formed and the second region 122 in which the number of recesses 91 is smaller than that in the first region 121 of the substrate W to measure the absorbance spectra of the first region 121 and the second region 122 of the substrate W. In the determination method according to the second embodiment, the embedded state of the recesses 91 is determined based on the difference between the integrated value of the intensity at a plurality of wavenumbers of the absorbance spectrum of the first region 121 and the integrated value of the intensity at a plurality of wavenumbers of the absorbance spectrum of the second region 122. Accordingly, the determination method according to the second embodiment can detect the occurrence of embedding defects while suppressing the influence of errors caused by the change in the environmental error factors.

Further, in the determination method according to the second embodiment, the second region 122 is adjacent to the first region 121. Accordingly, the determination method according to the second embodiment can measure the absorbance spectrum in a state where the second region and the first region have the same film formation state.

Further, in the determination method according to the second embodiment, the second region 122 is the boundary region of regions of the substrate W that will become chips. Accordingly, the determination method according to the second embodiment can detect the occurrence of embedding defects using the boundary region without providing the dedicated second region 122 on the substrate W.

Further, in the determination method according to the second embodiment, the spectroscopic measurement is performed on the first region 121 and the second region 122 of both the substrate W before film formation and the substrate W after film formation to measure the absorbance spectra of the first region 121 and the second region 122 of both the substrate W before film formation and the substrate W after film formation. In the determination method according to the second embodiment, the first difference between the integrated value of the intensity at a plurality of wavenumbers of the absorbance spectrum of the first region 121 of the substrate W before film formation and the integrated value of the intensity at a plurality of wavenumbers of the absorbance spectrum of the second region 122 thereof is obtained. Further, in the determination method according to the second embodiment, the second difference between the integrated value of the intensity at a plurality of wavenumbers of the absorbance spectrum of the first region 121 of the substrate W after film formation and the integrated value of the intensity at a plurality of wavenumbers of the absorbance spectrum of the second region 122 thereof is obtained. In the determination method according to the second embodiment, the embedded state of the recesses 91 is determined based on the difference between the first difference and the second difference. Accordingly, the determination method according to the second embodiment can accurately detect the occurrence of embedding defects in the recesses 91 due to the film 92 formed on the substrate W.

While the embodiments of the present disclosure have been described, the embodiments of the present disclosure are illustrative in all respects and are not restrictive. The above- described embodiments can be embodied in various forms. Further, the above-described embodiments may be omitted, replaced, or changed in various forms without departing from the scope of the appended claims and the gist thereof.

For example, in the above embodiments, the case in which the irradiator 81 is configured to be vertically movable and rotatable to change the incident angle and the irradiation position of light incident on the substrate W has been described, but the present disclosure is not limited thereto. For example, an optical element such as a mirror or a lens may be provided in an optical path of light irradiated from the irradiator 81 or an optical path of light incident on the detector 82, and the incident angle or the irradiation position of the light incident on the substrate W may be changed by the optical element.

Further, in the above embodiments, the case in which infrared light is transmitted near the center of the substrate W to determine the embedded state near the center of the substrate W has been described, but the present disclosure is not limited thereto. For example, an optical element such as a mirror or a lens that reflects light may be provided in the chamber 1, and the embedded states in a plurality of locations, such as the vicinity of the center of the substrate W, the vicinity of the periphery of the substrate W, and the like, may be determined by irradiating transmitted light or reflected light to the respective locations and detecting the transmitted light or the reflected light at the respective locations using the optical element.

Further, in the above embodiments, the case in which the substrate processing apparatus of the present disclosure is a single-chamber type film forming apparatus 100 having one chamber, but the present disclosure is not limited thereto. The substrate processing apparatus of the present disclosure may be a multi-chamber type film forming apparatus having a plurality of chambers.

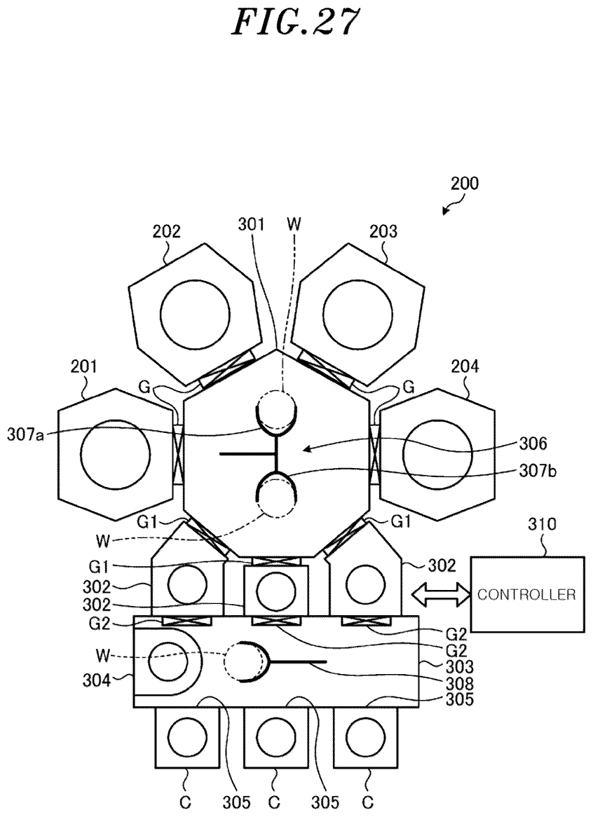

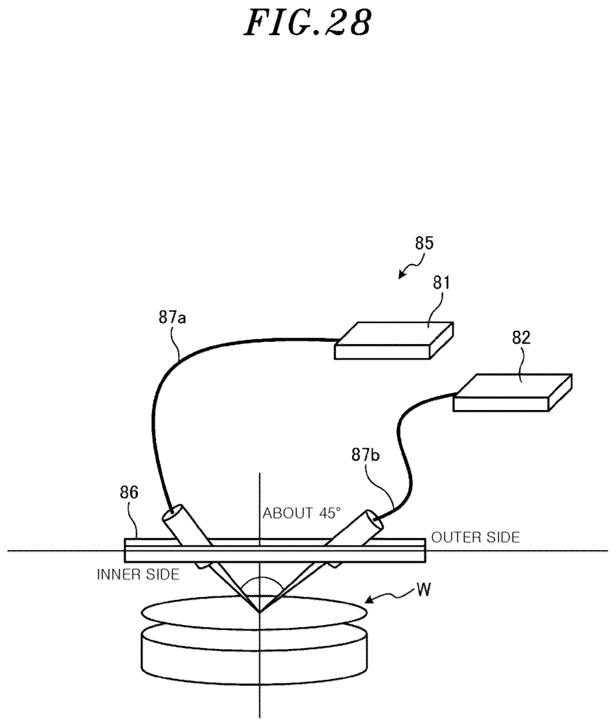

FIG. 27 is a schematic configuration diagram showing another example of the film forming apparatus 200 according to the embodiment. As shown in FIG. 27, the film forming apparatus 200 is a multi-chamber type film forming apparatus having four chambers 201 to 204. In the film forming apparatus 200, film formation is performed in each of the four chambers 201 to 204.

The chambers 201 to 204 are connected to four walls of the vacuum transfer chamber 301 having a heptagonal shape in plan view via gate valves G. The vacuum transfer chamber 301 is evacuated by a vacuum pump and maintained at a predetermined vacuum level. Three load-lock chambers 302 are connected to the other three walls of the vacuum transfer chamber 301 via gate valves G1. An atmospheric transfer chamber 303 is disposed on the opposite side of the vacuum transfer chamber 301 with the load-lock chambers 302 interposed therebetween. The three load-lock chambers 302 are connected to an atmospheric transfer chamber 303 via gate valves G2. The load-lock chambers 302 controls a pressure between an atmospheric pressure and a vacuum state when the substrate W is transferred between the atmospheric transfer chamber 303 and the vacuum transfer chamber 301.

Three carrier mounting ports 305 for mounting carriers (such as FOUP) C accommodating substrates W are disposed on the opposite wall of the wall of the atmospheric transfer chamber 303 to which the load-lock chambers 302 are attached. Further, an alignment chamber 304 for aligning the substrate W is disposed on the sidewall of the atmospheric transfer chamber 303. A downflow of clean air is formed in the atmospheric transfer chamber 303.

A transfer mechanism 306 is disposed in the vacuum transfer chamber 301. The transfer mechanism 306 transfers the substrate W to the chambers 201 to 204 and the load-lock chambers 302. The transfer mechanism 306 has two transfer arms 307a and 307b capable of moving independently.

A transfer mechanism 308 is disposed in the atmospheric transfer chamber 303. The transfer mechanism 308 transfers the substrate W to the carriers C, the load-lock chambers 302, and the alignment chamber 304.

The film forming apparatus 200 includes a controller 310. The overall operation of the film forming apparatus 200 is controlled by the controller 310.

In the film forming apparatus 200 configured as described above, a measurement part 85 for performing spectroscopic measurement on the substrate W may be disposed in a location other than the chambers 201 to 204. For example, in the film forming apparatus 200, the measurement part 85 for performing spectroscopic measurement on the substrate W is disposed in one of the vacuum transfer chamber 301, the load-lock chambers 302, the atmospheric transfer chamber 303, and the alignment chamber 304.

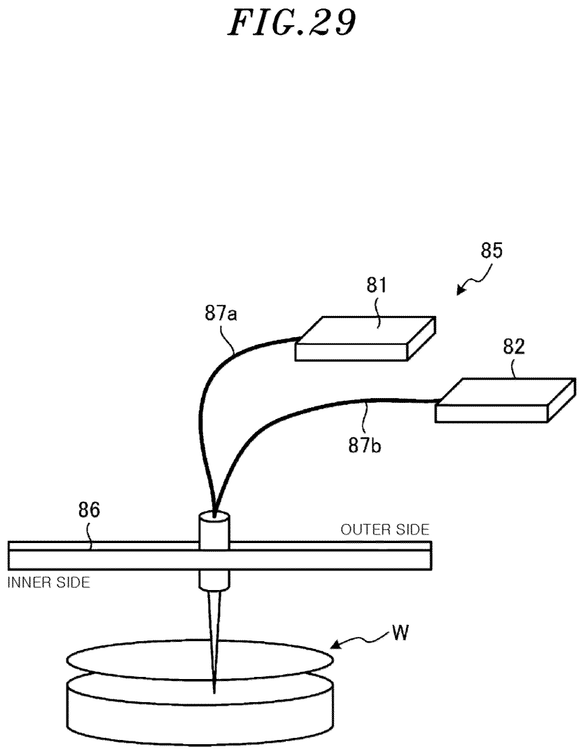

FIG. 28 shows an example of a schematic configuration of the measurement part 85 according to the embodiment. The measurement part 85 includes the irradiator 81 that irradiates light, and the detector 82 that can detect light. The irradiator 81 and the detector 82 are disposed outside a housing 86 such as the vacuum transfer chamber 301, the load-lock chambers 302, the atmospheric transfer chamber 303, and the alignment chamber 304. Light guiding members 87a and 87b such as optical fibers are connected to the irradiator 81 and the detecting part 82. The ends of the light guide members 87a and 87b are disposed in the housing 86. The light outputted from the irradiator 81 is outputted from the end of the light guide member 87a. The end of the light guide member 87a is disposed such that the light is incident on the substrate W at a predetermined incident angle (e.g.,) 45°. The end of the light guide member 87a is disposed such that the light reflected from the substrate W is incident thereon. The light incident on the end of the light guide member 87b is detected by the detector 82 via the light guide member 87b. The measurement part 85 performs spectroscopic measurement of the substrate W. The controller 310 measures the absorbance spectrum of the substrate W from the light received by the detector 82, and determines the embedded state of the recesses 91 based on the integrated value of the intensity at a plurality of wavenumbers of the measured absorbance spectrum of the substrate W. Accordingly, also in the film forming apparatus 200, the occurrence of embedding defects in the substrate W can be detected in-line. Further, the measurement part 85 may perform spectroscopic measurement by allowing light to be incident on the substrate W perpendicularly. FIG. 29 shows another example of the schematic configuration of the measurement part 85 according to the embodiment. In FIG. 29, the ends of the light guide members 87a and 87b disposed in the housing 86 are coaxial double optical fibers, and are disposed above the substrate W to be perpendicular to the substrate W. The light outputted from the irradiator 81 is outputted from the end of the light guide member 87a and incident on the substrate W perpendicularly. The light incident on the substrate W is reflected and incident on the end of the light guide member 87b. The light incident on the end of the light guide member 87b is detected by the detector 82 via the light guide member 87b. In this manner, the measurement part 85 may perform spectroscopic measurement by allowing light to be incident on the substrate W perpendicularly.

Further, in the above embodiments, the case in which the spectroscopic measurement is performed using infrared light has been described, but the present disclosure is not limited thereto. For example, when the recesses 91 of the pattern 90 formed on the substrate W have a relatively small depth (e.g., within 0.5 μm), the light used for the spectroscopic measurement may be short wavelength side light in infrared light, or light having a wavelength in a visible light range of about 200 μm to 1000 μm. In that case, the irradiator 81 and the detector 82 may not be angled. For example, as shown in FIG. 29, the spectroscopic measurement light may be performed by allowing light to be incident on the substrate W perpendicularly.

Further, as described above, the multi-chamber type single-substrate processing apparatus having one or multiple chambers for processing substrates one by one has been described as an example of the substrate processing apparatus of the present disclosure, but the present disclosure is not limited thereto. For example, it may be a batch type substrate processing apparatus capable of processing a plurality of substrates at once, or may be a carousel semi-batch type substrate processing apparatus.

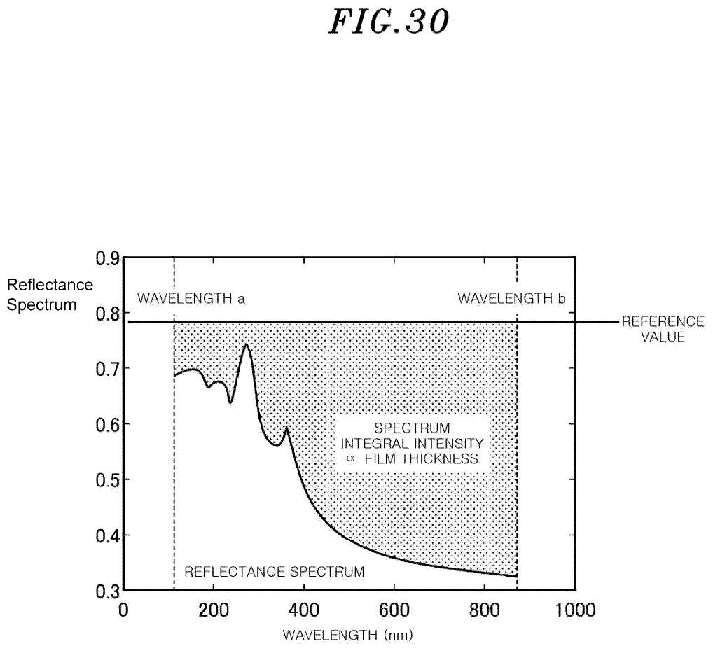

Further, in the above embodiments, the case in which the absorbance spectrum is a spectrum indicating absorbance for each wavenumber has been described, but the present disclosure is not limited thereto. The absorbance spectrum is considered to be equivalent to the area integrated value (difference) of the wavelength region of the reflectance spectrum obtained from the reflected light. The absorbance spectrum may be expressed as the amount of change in the reflectance spectrum. FIG. 30 shows an example of ae reflectance spectrum.

FIG. 30 shows an example of a reflectance spectrum of a predetermined reference sample. The reference sample was a bare silicon wafer. The reflectance spectrum is measured as follows. 1) The spectroscopic measurement of the reference sample is performed to obtain the output of the reflectance intensity in the wavelength region using a measuring device. 2) The reflectance intensity is converted to a reflectance. Specifically, the measurement value of the reflectance intensity for each wavelength of the reference sample is calibrated to an ideal absolute reflectance obtained from the simulation, and is used to calibrate the measured waveform, thereby obtaining the reflectance spectrum corresponding to the measured wavelength. 3) An area intensity S indicating the area intensity difference from the reference value is obtained using the following Eq. (1). The reference value may be any value. For example, the reference value is set to be larger than the maximum peak value of the reflectance spectrum.

$$area intensity S = {\int }_{wavelength a}^{wavelength b} f \text{} \{ reference value - reflectance of sample \} d ( wavelength ) \qquad ( Eq . 1 )$$

As shown in FIG. 30, the area intensity S is the area integrated value (difference) of the wavelength region of the reflectance spectrum. The absorbance spectrum is considered to be equivalent to the area intensity S. Therefore, in the above embodiments, the amount of change in the reflectance spectrum, such as the area intensity S or the like, may be used as the absorbance spectrum.

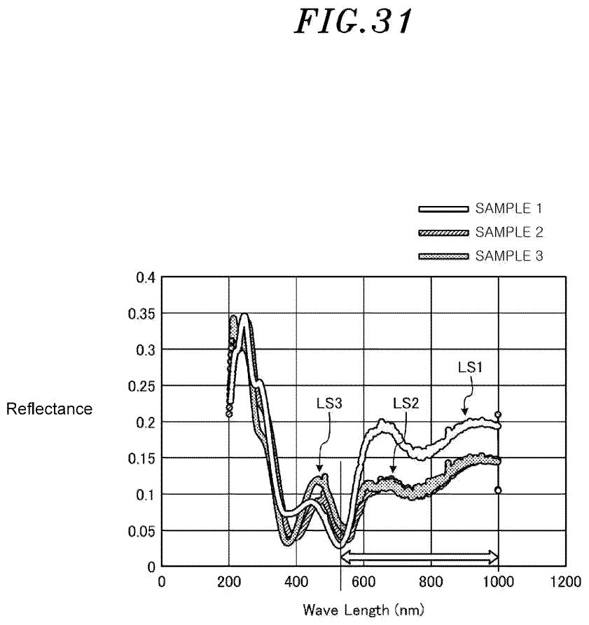

FIG. 31 shows an example of detection of the voids 93 using the reflectance spectrum according to the embodiment. FIG. 31 shows the reflectance spectra of three samples 1 to 3.The samples 1 to 3 are substrates W in which the recesses 91 of the pattern 90 are filled with SiN with a step difference of about 150 nm. In sample 1, the voids 93 have occurred in the recesses 91. In Samples 2 and 3, the voids 93 have not occurred in the recesses 91. A line LS1 shows the reflectance spectrum of sample 1 in which the voids 93 have occurred. Lines LS2 and LS3 show the reflectance spectra of samples 2 and 3 in which the voids 93 have not occurred. As shown in FIG. 31, the reflectance spectrum of the line LS1 where the voids 93 have occurred and the reflectance spectra of the lines LS2 and LS3 where the voids 93 have not occurred have different waveforms in the wavelength range greater than 500 nm. Therefore, the occurrence of the voids 93 can be detected by comparing the reflectance spectrum area in the wavelength range of 550 nm to 1000 nm or by obtaining the area integrated value (difference) of the wavelength region of the reflectance spectrum, for example.

Further, the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

Further, the following appendices are disclosed with respect to the above embodiments.

### Appendix 1

A determination method comprising:
a post-embedding measurement step for performing spectroscopic measurement on a substrate in which a pattern including a recess is formed, the recess having an embedding material embedded therein, and measuring an absorbance spectrum of the substrate having the embedding material embedded therein; and
a determination step for determining an embedded state of the recess based on an integrated value of an intensity of the measured absorbance spectrum of the substrate at a plurality of wavenumbers.

### Appendix 2

The determination method of Appendix 1, wherein the pattern is formed in each region of the substrate that will becomes a chip, and
a spot size of measurement light in the spectroscopic measurement is larger than the chip.

### Appendix 3

The determination method of Appendix 1 or 2, wherein in the determination step, the embedded state of the recess is determined based on the integrated value of the intensity of the absorbance spectrum in a predetermined wavenumber range including a wavenumber at which a peak occurs due to the embedded material in the absorbance spectrum of the substrate.

### Appendix 4

The determination method of Appendix 3, wherein the embedding material is a film containing SiO or SiN, and
the peak is a highest peak appearing in a range of 800 cm⁻¹ to 1100 cm⁻¹.

### Appendix 5

The determination method of Appendix 3, wherein the embedding material is a film containing SiO or SiN, and
the wavenumber range is 3000 cm⁻¹ to 10000 cm⁻¹.

### Appendix 6

The determination method of Appendix 3, wherein the embedding material is SiO, and the peak is 1080 cm⁻¹.

### Appendix 7

The determination method of Appendix 3 or 6, wherein the wavenumber range is 500 cm⁻¹ to 1400 cm⁻¹.

### Appendix 8

The determination method of any one of Appendices 1 to 7, wherein in the determination step, whether or not a void exists in the recess in which the embedding material is embedded is determined based on whether or not the integrated value is within a predetermined range or is greater than or equal to a predetermined threshold. (Appendix 9

The determination method of any one of Appendices 1 to 8, wherein in the spectroscopic measurement, light that tends to transmit through the substrate is irradiated, and light that has transmitted through the substrate or reflected light is detected. (Appendix 10

The determination method of any one of Appendices 1 to 9, wherein the substrate is a silicon substrate, and in the spectroscopic measurement, infrared light is irradiated to the substrate, and infrared light that has transmitted through the substrate or reflected infrared light is detected. (Appendix 11

The determination method of any one of Appendices 1 to 10, wherein in the post-embedding measurement step, the spectroscopic measurement is performed on a first region of the substrate in which the pattern is formed and a second region of the substrate in which the number of recesses is smaller compared to the first region to measure absorbance spectrum of the first region and the second region, and
in the determination step, the embedded state of the recess is determined based on a difference between an integrated value of an intensity at the plurality of wavenumbers of the absorbance spectrum of the first region and an integrated value of an intensity at the plurality of wavenumbers of the absorbance spectrum of the second region.

### Appendix 12

The determination method of Appendix 11, wherein the second region is a region near the first region.

### Appendix 13

The determination method of Appendix 11, wherein the second region is a boundary region of regions of the substrate that will become chips.

### Appendix 14

The determination method of any one of Appendices 1 to 13, further comprising:
a pre-embedding measurement step for performing spectroscopic measurement on the substrate before the embedding material is embedded in the recess and measuring an absorbance spectrum of the substrate before the embedding material is embedded; and
an embedding step for embedding the embedding material in the recess,
wherein the determination step, the embedded state of the recess is determined based on the difference between the integrated value of the intensity at the plurality of wavenumbers of the absorbance spectrum of the substrate before the embedding material is embedded in the recess and the integrated value of the intensity at the plurality of wavenumbers of the absorbance spectrum of the substrate in which the embedding material is embedded in the recess.

### Appendix 15

The determination method of Appendix 14, wherein in the pre-embedding measurement step and the post-embedding measurement step, the spectroscopic measurement is performed on a first region of the substrate where the pattern is formed and a second region of the substrate where the number of recesses is smaller compared to the first region to measure the absorbance spectra of the first region and the second region of the substrate, and
in the determination step, a first difference between the integrated value of the intensity at the plurality of wavenumbers of the absorbance spectrum of the first region of the substrate and the integrated value of the intensity at the plurality of wavenumbers of the absorbance spectrum of the second region of the substrate that are measured in the pre-embedding measurement step, and a second difference between the integrated value of the intensity at the plurality of wavenumbers of the absorbance spectrum of the first region of the substrate and the integrated value of the intensity of at the plurality of wavenumbers of the absorbance spectrum of the second region of the substrate that are measured in the post-embedding measurement step are obtained, and the embedded state of the recess is determined based on a difference between the first difference and the second difference.

### Appendix 16

The determination method of Appendix 15, wherein the second region is a region near the first region.

### Appendix 17

The determination method of Appendix 15, wherein the second region is a boundary region of regions of the substrate that will become chips.

### Appendix 18

A substrate processing apparatus comprising:
a light source configured to emit light to a substrate in which a pattern including a recess is formed and an embedding material is embedded in the recesses;
a light receiving mechanism configured to receive transmitted light emitted from the light source and transmitted through the substrate or reflected light emitted from the light source and reflected by the substrate; and
a controller,
wherein the controller executes:
measuring an absorbance spectrum of the substrate in which the embedding material is embedded from the reflected light or the transmitted light received by the light receiving mechanism; and
determining an embedded state of the recess based on the integrated value of the intensity at a plurality of wavenumbers of the measured absorbance spectrum of the substrate.

### Appendix 19

The substrate processing apparatus of Appendix 18, further comprising:
a substrate loading mechanism; and
an embedding processing chamber in which an embedding material is embedded in the recess,
wherein the light source and the light receiving mechanism are disposed at the substrate loading mechanism.

### Appendix 20

The substrate processing apparatus of Appendix 19, wherein the substrate loading mechanism includes a vacuum transfer chamber, a load-lock chamber, and an atmospheric transfer chamber, and
the light source and the light receiving mechanism are disposed at any one of the vacuum transfer chamber, the load-lock chamber, and the atmospheric transfer chamber.

### DESCRIPTION OF REFERENCE NUMERALS

W: substrate
1: chamber
2: placing table
6: lifter pin
10: RF power supply
15: gas supply source
16: shower head
60: controller
61: user interface
62: memory part
80a: window
80b: window
81: irradiator
82: detector
90: pattern
91: recess
92: film
92a: SiN film
93: void
95: region
96, 97: spot size
100: film forming apparatus
200: film forming apparatus
201 to 204: chamber

1. A determination method comprising:
a post-embedding measurement step for performing spectroscopic measurement on a substrate in which a pattern including a recess is formed, the recess having an embedding material embedded therein, and measuring an absorbance spectrum of the substrate having the embedding material embedded therein; and
a determination step for determining an embedded state of the recess based on an integrated value of an intensity of the measured absorbance spectrum of the substrate at a plurality of wavenumbers.

2. The determination method of claim 1, wherein the pattern is formed in each region of the substrate that will becomes a chip, and a spot size of measurement light in the spectroscopic measurement is larger than the chip.

3. The determination method of claim 1, wherein in the determination step, the embedded state of the recess is determined based on the integrated value of the intensity of the absorbance spectrum in a predetermined wavenumber range including a wavenumber at which a peak occurs due to the embedding material in the absorbance spectrum of the substrate.

4. The determination method of claim 3, wherein the embedding material is a film containing SiO or SiN, and the peak is a highest peak appearing in a range of 800 cm⁻¹ to 1100 cm⁻¹.

5. The determination method of claim 3, wherein the embedding material is a film containing SiO or SiN, and the predetermined wavenumber range is 3000 cm⁻¹ to 10000 cm⁻¹.

6. The determination method of claim 3, wherein the embedding material is SiO, and the peak is 1080 cm⁻¹.

7. The determination method of claim 3, wherein the predetermined wavenumber range is 500 cm⁻¹ to 1400 cm⁻¹.

8. The determination method of claim 1, wherein in the determination step, whether or not a void exists in the recess in which the embedding material is embedded is determined based on whether or not the integrated value is within a predetermined range or is greater than or equal to a predetermined threshold.

9. The determination method of claim 1, wherein in the spectroscopic measurement, light that tends to transmit through the substrate is irradiated, and light that has transmitted through the substrate or reflected light is detected.

10. The determination method of claim 1, wherein the substrate is a silicon substrate, and in the spectroscopic measurement, infrared light is irradiated to the substrate, and infrared light that has transmitted through the substrate or reflected infrared light is detected.

11. The determination method of claim 1, wherein in the post-embedding measurement step, the spectroscopic measurement is performed on a first region of the substrate in which the pattern is formed and a second region of the substrate in which a number of recesses is smaller compared to the first region to measure absorbance spectrum of the first region and the second region, and
in the determination step, the embedded state of the recess is determined based on a difference between an integrated value of an intensity at the plurality of wavenumbers of the absorbance spectrum of the first region and an integrated value of an intensity at the plurality of wavenumbers of the absorbance spectrum of the second region.

12. The determination method of claim 11, wherein the second region is a region near the first region.

13. The determination method of claim 11, wherein the second region is a boundary region of regions of the substrate that will become chips.

14. The determination method of claim 1, further comprising:
a pre-embedding measurement step for performing spectroscopic measurement on the substrate before the embedding material is embedded in the recess and measuring an absorbance spectrum of the substrate before the embedding material is embedded; and
an embedding step for embedding the embedding material in the recess,
wherein the determination step, the embedded state of the recess is determined based on a difference between the integrated value of the intensity at the plurality of wavenumbers of the absorbance spectrum of the substrate before the embedding material is embedded in the recess and the integrated value of the intensity at the plurality of wavenumbers of the absorbance spectrum of the substrate in which the embedding material is embedded in the recess.

15. The determination method of claim 14, wherein in the pre-embedding measurement step and the post-embedding measurement step, the spectroscopic measurement is performed on a first region of the substrate where the pattern is formed and a second region of the substrate where a number of recesses is smaller compared to the first region to measure the absorbance spectra of the first region and the second region of the substrate, and
in the determination step, a first difference between the integrated value of the intensity at the plurality of wavenumbers of the absorbance spectrum of the first region of the substrate and the integrated value of the intensity at the plurality of wavenumbers of the absorbance spectrum of the second region of the substrate that are measured in the pre-embedding measurement step, and a second difference between the integrated value of the intensity at the plurality of wavenumbers of the absorbance spectrum of the first region of the substrate and the integrated value of the intensity of at the plurality of wavenumbers of the absorbance spectrum of the second region of the substrate that are measured in the post-embedding measurement step are obtained, and the embedded state of the recess is determined based on a difference between the first difference and the second difference.

16. The determination method of claim 15, wherein the second region is a region near the first region.

17. The determination method of claim 15, wherein the second region is a boundary region of regions of the substrate that will become chips.

18. A substrate processing apparatus comprising:
a light source configured to emit light to a substrate in which a pattern including a recess is formed and an embedding material is embedded in the recess;
a light receiving mechanism configured to receive transmitted light emitted from the light source and transmitted through the substrate or reflected light emitted from the light source and reflected by the substrate; and
a controller,
wherein the controller executes:
measuring an absorbance spectrum of the substrate in which the embedding material is embedded from the reflected light or the transmitted light received by the light receiving mechanism; and
determining an embedded state of the recess based on an integrated value of an intensity at a plurality of wavenumbers of the measured absorbance spectrum of the substrate.

19. The substrate processing apparatus of claim 18, further comprising:
a substrate loading mechanism; and
an embedding processing chamber in which an embedding material is embedded in the recess,
wherein the light source and the light receiving mechanism are disposed at the substrate loading mechanism.

20. The substrate processing apparatus of claim 19, wherein the substrate loading mechanism includes a vacuum transfer chamber, a load-lock chamber, and an atmospheric transfer chamber, and
the light source and the light receiving mechanism are disposed at any one of the vacuum transfer chamber, the load-lock chamber, and the atmospheric transfer chamber.
